(19) United States
(12) Patent Application Publication
(10) Pub. No.: US 2010/0013049 A1
(43) Pub. Date: Jan. 21, 2010

(54) SEMICONDUCTOR MEMORY DEVICE AND METHOD FOR MANUFACTURING SAME

(75) Inventors: Hiroyasu Tanaka, Tokyo (JP); Megumi Ishiduki, Kanagawa-ken (JP); Yosuke Komori, Kanagawa-ken (JP); Yoshiaki Fukuzumi, Kanagawa-ken (JP); Masaru Kito, Kanagawa-ken (JP); Hideaki Aochi, Kanagawa-ken (JP); Ryota Katsumata, Kanagawa-ken (JP); Masaru Kidoh, Tokyo (JP); Yasuyuki Matsuoka, Kanagawa-ken (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Kabushiki Kaisha Toshiba, Tokyo (JP)

(21) Appl. No.: 12/504,959

(22) Filed: Jul. 17, 2009

(30) Foreign Application Priority Data
Jul. 18, 2008 (JP) 2008-187787

(51) Int. Cl. H01L 23/522; H01L 21/02; H01L 21/768

(52) U.S. Cl. 257/532; 438/396; 257/751; 438/637; 257/E23.144; 257/E21.008; 257/E21.576

(57) ABSTRACT

A first multilayer body is formed by alternately layering dielectric films and electrode films on a substrate. Then, an end portion of the first multilayer body is processed into a staircase shape, and a first interlayer dielectric film is formed around the first multilayer body. Next, a plurality of contact holes having a diameter decreasing downward are formed in the first interlayer dielectric film so that the contact holes reach respective end portions of the electrode films. Then, a sacrificial material is buried in the contact holes. Next, a second multilayer body is formed immediately above the first multilayer body, and a second interlayer dielectric film is formed around the second multilayer body. Thereafter, a plurality of contact holes having a diameter decreasing downward are formed in the second interlayer dielectric film to communicate with the respective contact holes formed in the first interlayer dielectric film. Then, the sacrificial material is removed and a contact is buried inside the contact holes. The contact has a step difference.

### CROSS-REFERENCE TO RELATED APPLICATIONS

This application is based upon and claims the benefits of priority from the prior Japanese Patent Application No. 2008-187787, filed on Jul. 18, 2008; the entire contents of which are incorporated herein by reference.

### BACKGROUND OF THE INVENTION

1. Field of the Invention

This invention relates to a semiconductor memory device and a method for manufacturing the same, and more particularly to a semiconductor memory device with a plurality of dielectric films and electrode films alternately layered on a substrate, and a method for manufacturing the same.

2. Background Art

Conventionally, semiconductor memory devices such as flash memories have been fabricated by two-dimensionally integrating elements on the surface of a silicon substrate. Increasing the memory capacity of such a flash memory has to rely on downscaling by decreasing the dimensions of each element. However, such downscaling has been difficult in terms of cost and technology. Downscaling requires improvement in photolithography techniques, but a design rule of approximately 40 nm (nanometers) is the resolution limit of the current technique for ArF immersion exposure. Further downscaling requires introduction of an EUV (extreme ultraviolet) exposure apparatus, but this is impractical because of very high cost of the EUV exposure apparatus. Even if downscaling is achieved by using the EUV exposure apparatus, it is anticipated that the breakdown voltage between devices, for example, reaches a physical limit unless the driving voltage and the like are scaled, and the device is probably difficult to operate.

To solve these problems, numerous ideas for three-dimensionally integrating elements are proposed. However, a three-dimensional device typically requires at least three lithography steps for each layer. Hence, cost reduction is difficult despite three-dimensional construction. Contrarily, layering four films or more results in cost increase.

In view of this problem, the present inventor and others proposed a simultaneously processed three-dimensional multilayer memory (see, e.g., JP-A-2007-266143). In this technique, electrode films and dielectric films are alternately layered on a silicon substrate to form a multilayer body, and then through holes are simultaneously formed in this multilayer body. A charge storage layer is formed on the side surface of the through hole, and silicon is buried inside the through hole to form a silicon pillar. Thus, a memory cell is formed at each intersection between the electrode film and the silicon pillar. Furthermore, the end portion of the multilayer body is processed into a staircase shape, an interlayer dielectric film is provided around the multilayer body so as to overlap the staircase-shaped end portion, and contacts are buried in the interlayer dielectric film so as to be connected to the end portions of the electrode films. A plurality of metal interconnects are provided above the interlayer dielectric film and connected to the end portions of the electrode films through the contacts. Thus, the potential of each electrode film can be independently controlled through the metal interconnect and the contact.

In this simultaneously processed three-dimensional multilayer memory, information can be recorded by controlling the potential of each electrode film and each silicon pillar to transfer charge between the silicon pillar and the charge storage layer. In this technique, a plurality of electrode films are layered on the silicon substrate to reduce the chip area per bit, achieving cost reduction. Furthermore, because the multilayer body can be simultaneously processed to form a three-dimensional multilayer memory, increase in the number of layered films does not result in increasing the number of lithography steps, and cost increase can be reduced.

However, in this technique, increase in the number of layered electrode films results in increasing the height difference between the lower electrode film and the upper metal interconnect. This increases the aspect ratio of the contact and causes a problem of being difficult to form the contact. Currently, the upper limit of aspect ratio of the contact that can be formed is approximately 10, for example. Hence, this upper limit of aspect ratio constrains the number of layered films. Alternatively, increasing the diameter of the contact may be contemplated. However, this results in increasing the chip area and canceling out the advantage of the multilayer configuration.

### SUMMARY OF THE INVENTION

According to an aspect of the invention, there is provided a semiconductor memory device including: a substrate; a plurality of multilayer bodies stacked on the substrate, each of multilayer body including a plurality of dielectric films and a plurality of electrode films that are alternately layered, and having an end portion of a staircase shape; a plurality of interlayer dielectric films provided around the respective multilayer bodies; and a plurality of contacts buried so as to penetrate through the plurality of interlayer dielectric films and connected to respective end portions of the electrode films, the contact having a step difference at a position that is located between the interlayer dielectric films.

According to another aspect of the invention, there is provided a method for manufacturing a semiconductor memory device, including: forming a first multilayer body by alternately layering a plurality of dielectric films and a plurality of electrode films on a substrate; processing an end portion of the first multilayer body into a staircase shape; forming a first interlayer dielectric film around the first multilayer body; forming a first contact hole having a diameter decreasing downward in the first interlayer dielectric film so that the first contact hole reaches an end portion of the electrode film; burying a sacrificial material in the first contact hole; forming a second multilayer body by alternately layering a plurality of dielectric films and a plurality of electrode films immediately above the first multilayer body; forming a second interlayer dielectric film around the second multilayer body; forming a second contact hole having a diameter decreasing downward in the second interlayer dielectric film so that the second contact hole reaches the first contact hole; removing the sacrificial material; and burying a contact inside the first contact hole and the second contact hole.

### BRIEF DESCRIPTION OF THE DRAWINGS

FIG. 1 is a perspective view illustrating a semiconductor memory device according to a first embodiment of the invention;

FIG. 2 is a cross-sectional view illustrating the semiconductor memory device according to the first embodiment;

FIG. 3 is a cross-sectional view illustrating an end portion of a multilayer body in the semiconductor memory device according to the first embodiment;

FIG. 4A is a schematic plan view showing an example step difference in a contact;

FIG. 4B is a schematic cross-sectional view taken along line A-A′ shown in FIG. 4A;

FIG. 4C is a schematic cross-sectional view taken along line B-B′ shown in FIG. 4A;

FIG. 5A is a schematic plan view showing another example step difference in a contact;

FIG. 5B is a schematic cross-sectional view taken along line C-C′ shown in FIG. 5A;

FIG. 5C is a schematic cross-sectional view taken along line D-D′ shown in FIG. 5A;

FIG. 6 is a process cross-sectional view illustrating a method for manufacturing a semiconductor memory device according to the first embodiment;

FIG. 7 is a process cross-sectional view illustrating the method for manufacturing the semiconductor memory device according to the first embodiment;

FIG. 8 is a process cross-sectional view illustrating the method for manufacturing the semiconductor memory device according to the first embodiment;

FIG. 9 is a process cross-sectional view illustrating the method for manufacturing the semiconductor memory device according to the first embodiment;

FIG. 10 is a process cross-sectional view illustrating the method for manufacturing the semiconductor memory device according to the first embodiment;

FIG. 11 is a process cross-sectional view illustrating the method for manufacturing the semiconductor memory device according to the first embodiment;

FIG. 12 is a process cross-sectional view illustrating the method for manufacturing the semiconductor memory device according to the first embodiment;

FIG. 13 is a process cross-sectional view illustrating the method for manufacturing the semiconductor memory device according to the first embodiment;

FIG. 14 is a cross-sectional view illustrating a semiconductor memory device according to a second embodiment of the invention of the invention;

FIG. 15 is a process cross-sectional view illustrating a method for manufacturing a semiconductor memory device according to the second embodiment;

FIG. 16 is a process cross-sectional view illustrating the method for manufacturing the semiconductor memory device according to the second embodiment;

FIG. 17 is a process cross-sectional view illustrating the method for manufacturing the semiconductor memory device according to the second embodiment;

FIG. 18 is a process cross-sectional view illustrating the method for manufacturing the semiconductor memory device according to the second embodiment;

FIG. 19 is a process cross-sectional view illustrating the method for manufacturing the semiconductor memory device according to the second embodiment;

FIG. 20 is a process cross-sectional view illustrating the method for manufacturing the semiconductor memory device according to the second embodiment;

FIG. 21 is a process cross-sectional view illustrating the method for manufacturing the semiconductor memory device according to the second embodiment;

FIG. 22 is a process cross-sectional view illustrating the method for manufacturing the semiconductor memory device according to the second embodiment;

FIG. 23 is a process cross-sectional view illustrating the method for manufacturing the semiconductor memory device according to the second embodiment;

FIG. 24 is a process cross-sectional view illustrating the method for manufacturing the semiconductor memory device according to the second embodiment;

FIG. 25 is a process cross-sectional view illustrating a method for manufacturing a semiconductor memory device according to a third embodiment of the invention; and

FIGS. 26A and 26B are schematic cross-sectional views illustrating the operation and effect of the third embodiment, FIG. 26A shows the case where a contact is in contact with only an upper surface of an electrode film, and FIG. 26B shows the case where a contact is in contact with an edge of an electrode film.

### DETAILED DESCRIPTION OF THE INVENTION

Embodiments of the invention will be described with reference to the drawings.

At the outset, a first embodiment of the invention is described.

The semiconductor memory device according to this embodiment is characterized in that it is a simultaneously processed three-dimensional multilayer memory, where a plurality of multilayer bodies, each including a plurality of layered electrode films, are stacked on a substrate, and contact holes are formed in a plurality of steps for each multilayer body. This results in increasing the total number of layered electrode films, increasing the aspect ratio of the contact, and forming a step difference at the joint of the contact.

In the following, the overall configuration of the semiconductor memory device is briefly described to clarify the position and function of electrode films, contacts, and so forth in the semiconductor memory device according to this embodiment, and then the characteristic portion of this embodiment is described in detail.

First, the overall configuration of the semiconductor memory device is described.

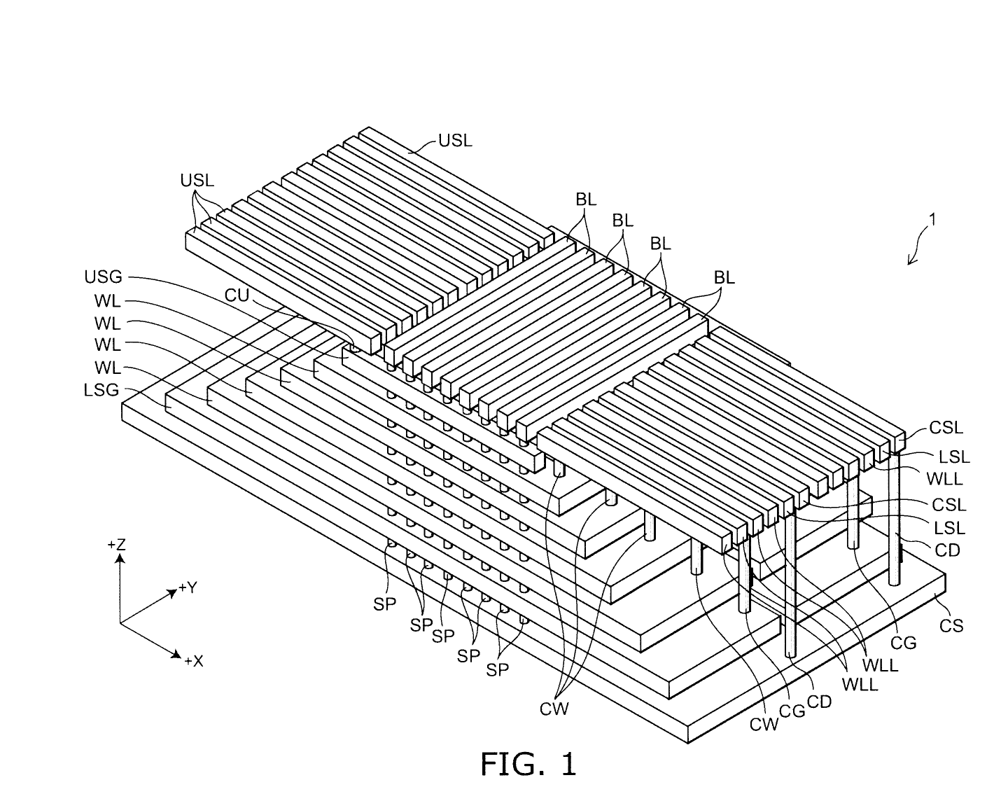

FIG. 1 is a perspective view illustrating a semiconductor memory device according to this embodiment.

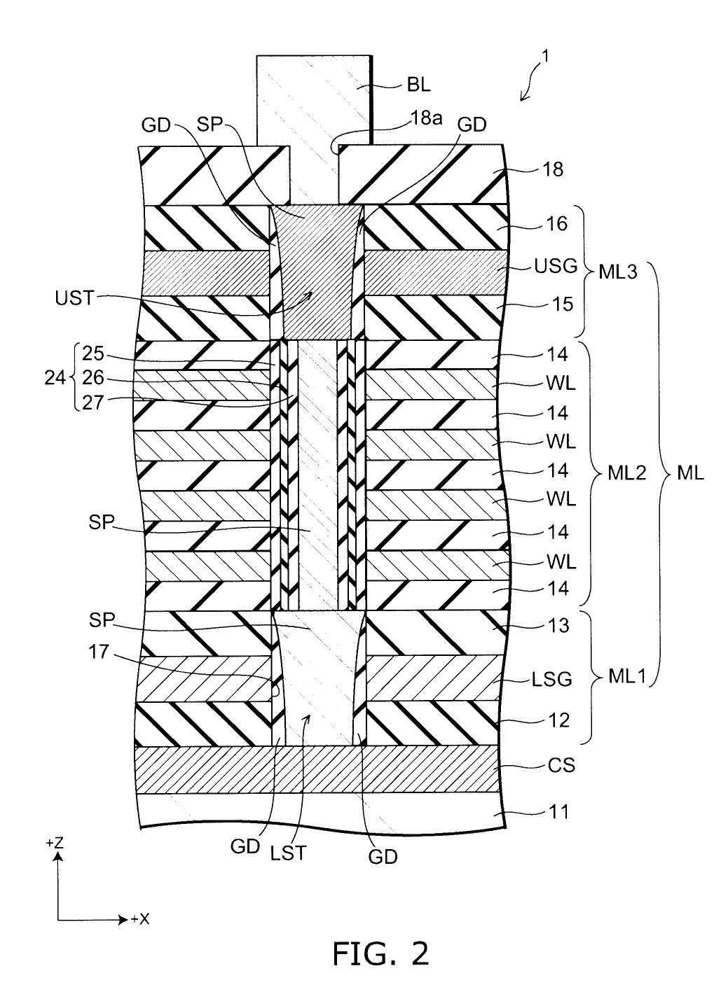

FIG. 2 is a cross-sectional view illustrating the semiconductor memory device according to this embodiment.

In FIG. 1, for clarity of illustration, only the conductive portions are shown, and the dielectric portions are not shown. Furthermore, illustration of the silicon substrate 11 (see FIG. 2) other than the cell source CS is also omitted.

As shown in FIGS. 1 and 2, the semiconductor memory device 1 (hereinafter also simply referred to as “device 1”) according to this embodiment is a nonvolatile semiconductor memory device, and more specifically a three-dimensional multilayer flash memory. The device 1 includes a silicon substrate 11 illustratively made of single crystal silicon. A device isolation (not shown) is formed at a desired position in an upper portion of the silicon substrate 11. A rectangular memory array region is doped with impurities to form a semiconductor region serving as a cell source CS.

A dielectric film 12 is provided on the silicon substrate 11 immediately above the cell source CS, a lower select gate LSG illustratively made of amorphous silicon is provided thereon, and a dielectric film 13 is provided thereon. The dielectric film 12, the lower select gate LSG, and the dielectric film 13 constitute a lower gate multilayer body ML1.

Above the lower gate multilayer body ML1 is formed a memory multilayer body ML2 in which a plurality of dielectric films 14 and a plurality of electrode films WL are alternately layered. The electrode film WL is illustratively formed from amorphous silicon, which is given P⁺-type conductivity by being doped with acceptor such as boron, and serves as a word line. The dielectric film 14 is illustratively formed from silicon oxide and serves as an interlayer dielectric film insulating the electrode films WL from each other. It is noted that as described later, although the memory multilayer body ML2 is divided into a plurality of multilayer bodies along the layering direction in this embodiment, FIG. 2 shows them as one multilayer body ML2. Furthermore, although FIGS. 1 and 2 show only four electrode films WL, more electrode films WL can be provided according to this embodiment.

A dielectric film 15 is provided on the memory multilayer body ML2, and an upper select gate USG illustratively made of amorphous silicon is provided thereon, and a dielectric film 16 is provided thereon. The dielectric film 15, the upper select gate USG, and the dielectric film 16 constitute an upper gate multilayer body ML3.

In the following, for convenience of description, an XYZ orthogonal coordinate system is herein introduced. In this coordinate system, the two directions parallel to the upper surface of the silicon substrate 11 and orthogonal to each other are referred to as the X and Y directions, and the direction orthogonal to both the X and Y directions, that is, the layering direction of the dielectric films 14 and the electrode films WL, is referred to as the Z direction.

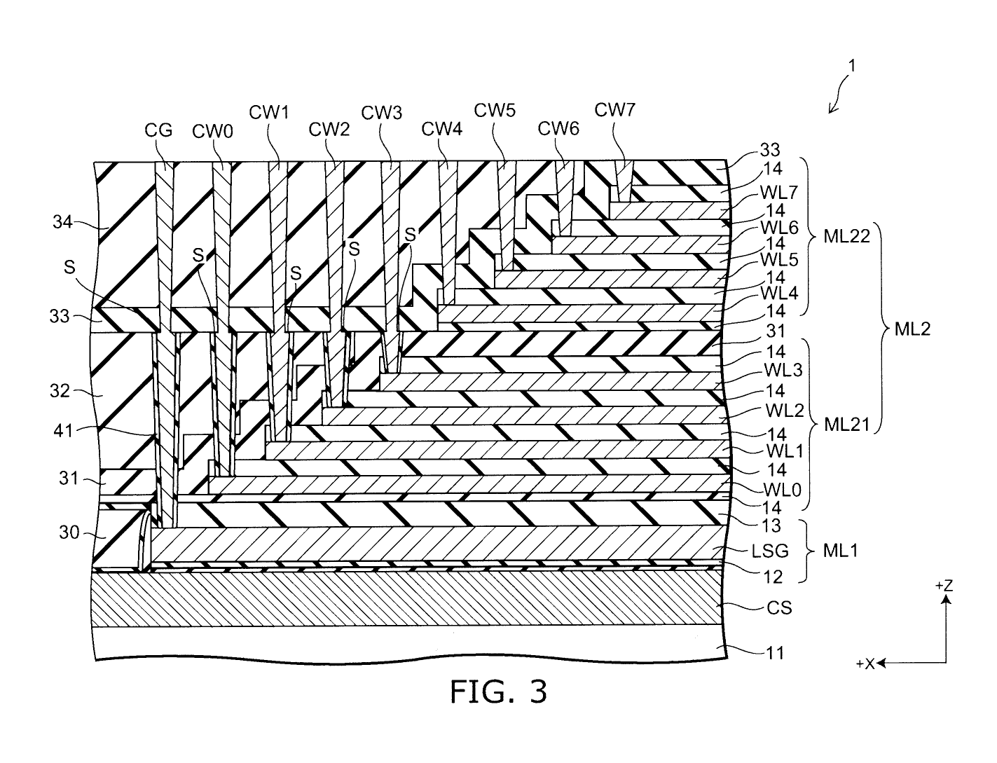

The X-direction length of the electrode films WL becomes shorter toward the upside. As viewed from above (+Z direction), each electrode film WL is located inside the electrode films WL, the lower select gate LSG, and the cell source CS located therebelow. Furthermore, the upper select gate USG is located inside the uppermost electrode film WL. Thus, the end portion of the memory multilayer body ML2 is shaped like a staircase. An interlayer dielectric film (see FIG. 3) is provided in the ±X-direction and ±Y-direction region as viewed from the memory multilayer body ML2.

Thus, the lower gate multilayer body ML1, the memory multilayer body ML2, and the upper gate multilayer body ML3 are stacked in this order on the silicon substrate 11. The lower gate multilayer body ML1, the memory multilayer body ML2, and the upper gate multilayer body ML3 (hereinafter also collectively referred to as “multilayer body ML”) are provided in a plurality along the Y direction.

The upper select gate USG is formed by dividing one conductive film along the Y direction into a plurality of conductive members, each shaped like an interconnect line extending in the X direction. In contrast, the electrode film WL and the lower select gate LSG are not divided in each multilayer body ML, but are each formed into one conductive film parallel to the XY plane. Furthermore, the cell source CS is also not divided, but is formed into one layer-shaped conductive region parallel to the XY plane so as to connect the immediately underlying regions of the plurality of multilayer bodies ML.

The multilayer body ML includes a plurality of through holes 17 extending in the layering direction (Z direction). Each through hole 17 penetrates entirely through the multilayer body ML. Furthermore, the through holes 17 are arranged in a matrix configuration along the X and Y directions, for example.

Inside each through hole 17 is buried a silicon pillar SP. The silicon pillar SP is formed from a semiconductor, such as polycrystalline silicon or amorphous silicon, doped with impurities. The silicon pillar SP is shaped like a column, such as a cylindrical column, extending in the Z direction. The silicon pillar SP is provided throughout the length of the multilayer body ML in the layering direction, and its lower end is connected to the cell source CS.

A dielectric film 18 is provided on the upper gate multilayer body ML3, and a plurality of bit interconnects BL extending in the Y direction are provided on the dielectric film 18. The bit interconnect BL is formed from metal, such as tungsten (W), aluminum (Al), or copper (Cu). It is noted that the term “metal” used herein includes alloys as well as pure metals. Each bit interconnect BL is provided to pass immediately above one column of silicon pillars SP arranged along the Y direction, and is connected to the upper end of the silicon pillars SP through via holes 18a formed in the dielectric film 18. Thus, the silicon pillar SP is connected between the bit interconnect BL and the cell source CS. Furthermore, the silicon pillars SP in different columns extending in the Y direction are connected to different bit interconnects BL.

Furthermore, a plurality of upper select gate interconnects USL extending in the X direction are provided on the −X-direction side of the region including the bit interconnects BL. The upper select gate interconnect USL is formed from metal, such as tungsten, aluminum, or copper. The number of upper select gate interconnects USL is equal to the number of upper select gates USG, and each upper select gate interconnect USL is connected to a corresponding one of the upper select gates USG through a contact CU.

Furthermore, on the +X-direction side of the region including the bit interconnects BL, for each multilayer body ML, a plurality of word interconnects WLL extending in the X direction, one lower select gate interconnect LSL extending in the X direction, and one cell source interconnect CSL extending in the X direction are provided. The word interconnect WLL, the lower select gate interconnect LSL, and the cell source interconnect CSL are formed from metal, such as tungsten, aluminum, or copper. The number of word interconnects WLL for each multilayer body ML is equal to the number of electrode films WL serving as word lines, and each word interconnect WLL is connected to a corresponding one of the electrode films WL through a contact CW. The lower select gate interconnect LSL is connected to the lower select gate LSG through a contact CG, and the cell source interconnect CSL is connected to the cell source CS through a contact CD. The contacts CW are formed in a region immediately above the electrode film WL to which they are connected, the region lying out of the overlying electrode film WL on the +X-direction side.

The bit interconnect BL, the upper select gate interconnect USL, the word interconnect WLL, the lower select gate interconnect LSL, and the cell source interconnect CSL are identical in the position along the Z direction, thickness, and material, and illustratively formed by patterning one metal film. The interconnects are insulated from each other by an interlayer dielectric film (not shown).

As shown in FIG. 2, in the cylindrical space between the side surface of the through hole 17 and the portion of the silicon pillar SP located in the multilayer body ML2 (this portion being hereinafter also referred to as “center portion of the silicon pillar”), an ONO film (oxide-nitride-oxide film) 24 is provided. The ONO film 24 includes a dielectric layer 25, a charge storage layer 26, and a dielectric layer 27 layered in this order from outside, that is, the electrode film WL side. The dielectric layer 25 is in contact with the dielectric film 14 and the electrode film WL, and the dielectric layer 27 is in contact with the silicon pillar SP. The dielectric layers 25 and 27 are illustratively made of silicon oxide (SiO₂), and the charge storage layer 26 is illustratively made of silicon nitride (SiN).

Thus, the center portion of the silicon pillar SP serves as a channel, the electrode film WL serves as a control gate, and the charge storage layer 26 serves as a floating gate, so that an SGT (surrounding gate transistor) serving as a memory cell is formed at the intersection between the silicon pillar SP and the electrode film WL. The SGT is a transistor having a structure in which the gate electrode surrounds the channel.

Consequently, as many memory cells as the electrode films WL are arranged in a line in the Z direction along one silicon pillar SP and therearound to constitute one memory string. Furthermore, a plurality of silicon pillars SP are arranged in a matrix configuration along the X and Y directions. Hence, in the memory multilayer body ML2, a plurality of memory cells are three-dimensionally arranged along the X, Y, and Z direction.

On the other hand, a gate dielectric film GD is provided in the cylindrical space between the side surface of the through hole 17 and the portion of the silicon pillar SP located in the lower gate multilayer body ML1 (this portion being also hereinafter referred to as “lower portion of the silicon pillar”). Thus, in the lower gate multilayer body ML1, a lower select transistor LST is formed with the lower portion of the silicon pillar SP serving as a channel and the lower select gate LSG serving as a gate. The lower select transistor LST is also an SGT, like the aforementioned memory cell.

Furthermore, a gate dielectric film GD is provided also in the cylindrical space between the side surface of the through hole 17 and the portion of the silicon pillar SP located in the upper gate multilayer body ML3 (this portion being also hereinafter referred to as “upper portion of the silicon pillar”). Thus, in the upper gate multilayer body ML3, an upper select transistor UST is formed with the upper portion of the silicon pillar SP serving as a channel and the upper select gate USG serving as a gate. The upper select transistor UST is also an SGT. The lower select transistor LST and the upper select transistor UST do not serve as memory cells, but serve to select a silicon pillar SP.

Moreover, the device 1 includes a driver circuit for applying a potential to the upper end of the silicon pillar SP through the bit interconnect BL, a driver circuit for applying a potential to the lower end of the silicon pillar SP through the cell source interconnect CSL, the contact CD, and the cell source CS, a driver circuit for applying a potential to the upper select gate USG through the upper select gate interconnect USL and the contact CU, a driver circuit for applying a potential to the lower select gate LSG through the lower select gate interconnect LSL and the contact CG, and a driver circuit for applying a potential to each word line WL through the word interconnect WLL and the contact CW (all the driver circuits being not shown). P-wells and N-wells (not shown) are formed in the circuit region including these driver circuits, and transistors and other elements are formed in these wells.

Thus, in the device 1, the X coordinate of a memory cell is selected by selecting a bit line BL, the Y coordinate of the memory cell is selected by selecting an upper select gate USG to bring the upper select transistor UST into the conducting or non-conducting state, and the Z coordinate of the memory cell is selected by selecting an electrode film WL serving as a word line. Information is stored by injecting electrons into the charge storage layer 26 of the selected memory cell. The information stored in the memory cell is read by passing a sense current through the silicon pillar SP that extends through the memory cell.

Next, the characteristic portion of this embodiment is described in detail.

FIG. 3 is a cross-sectional view illustrating the end portion of the multilayer body in the semiconductor memory device according to this embodiment.

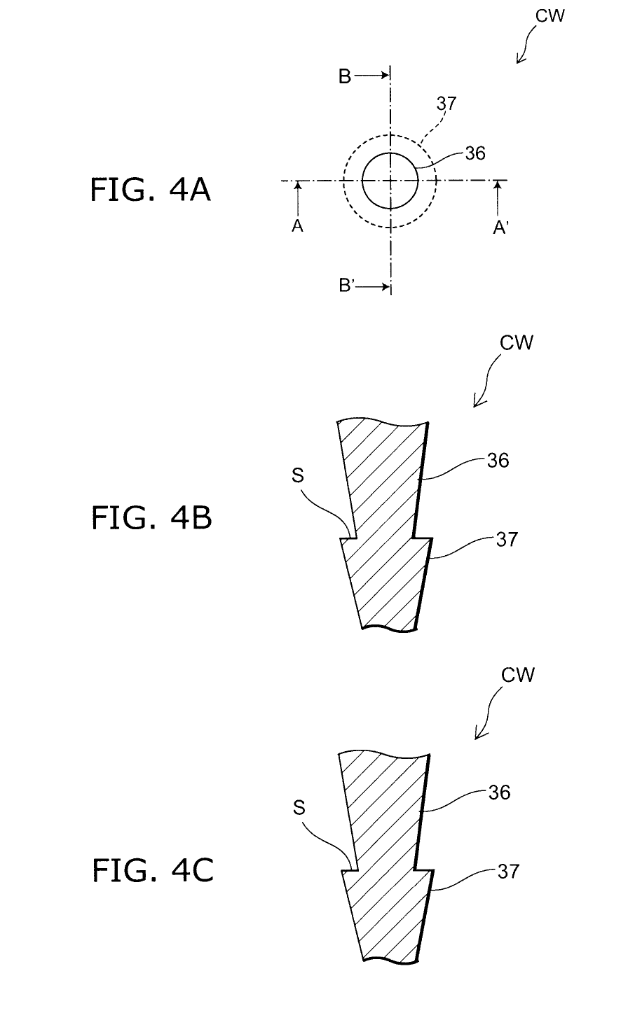

FIG. 4A is a schematic plan view showing an example step difference in the contact, FIG. 4B is a schematic cross-sectional view taken along line A-A′ shown in FIG. 4A, and FIG. 4C is a schematic cross-sectional view taken along line B-B′ shown in FIG. 4A.

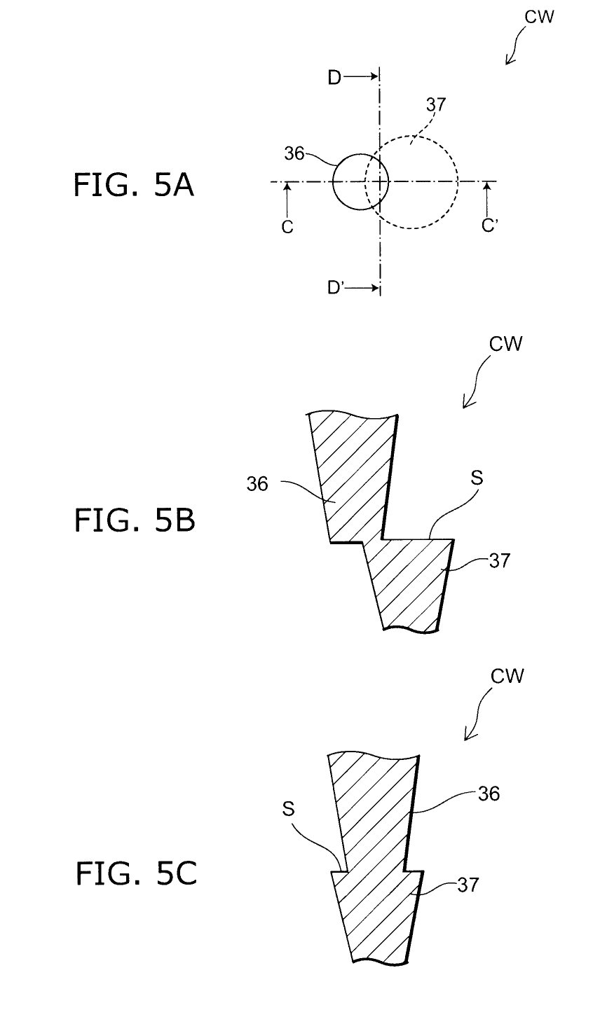

FIG. 5A is a schematic plan view showing another example step difference in the contact, FIG. 5B is a schematic cross-sectional view taken along line C-C′ shown in FIG. 5A, and FIG. 5C is a schematic cross-sectional view taken along line D-D′ shown in FIG. 5A.

As shown in FIG. 3, in this embodiment, the memory multilayer body ML2 is vertically divided into a plurality of stages, and the multilayer body of each stage includes a plurality of electrode films WL. In the example shown in FIG. 3, the memory multilayer body ML2 is divided into a lower multilayer body ML21 and an upper multilayer body ML22.

An interlayer dielectric film 30 is provided on the silicon substrate 11 around the lower gate multilayer body ML1, that is, in the X-direction and Y-direction region as viewed from the lower gate multilayer body ML1. The interlayer dielectric film 30 is illustratively formed from silicon oxide (SiO₂). The height of the upper surface of the interlayer dielectric film 30 is generally equal to the height of the upper surface of the lower gate multilayer body ML1.

The aforementioned multilayer body ML21 is provided immediately above the lower gate multilayer body ML1. In the multilayer body ML21, four electrode films WL0-WL3 serving as word lines are layered, and a dielectric film 14 is provided between the electrode films. As described above, the end portion of the multilayer body ML21 is shaped like a staircase.

An etching stopper film 31 is provided above the multilayer body ML21 and the interlayer dielectric film 30 so as to cover them. The etching stopper film 31 is illustratively formed from silicon nitride (SiN). The etching stopper film 31 covers also the staircase-shaped end portion of the multilayer body ML21, and this covering portion is shaped like a staircase, reflecting the shape of the end portion of the multilayer body ML21. That is, it includes a generally flat portion and a generally vertical portion for each electrode film WL.

An interlayer dielectric film 32 is provided on the etching stopper film 31 immediately above the interlayer dielectric film 30 and immediately above the staircase-shaped portion of the multilayer body ML21, that is, around the multilayer body ML21. The interlayer dielectric film 32 is illustratively formed from BPSG (Boro-Phospho Silicate Glass, a silicon glass doped with boron and phosphorus). The height of the upper surface of the interlayer dielectric film 32 is generally equal to the height of the upper surface of the etching stopper film 31 immediately above the multilayer body ML21.

The aforementioned multilayer body ML22 is provided on the etching stopper film 31 immediately above the upper surface of the multilayer body ML21. In the multilayer body ML22, four electrode films WL4-WL7 serving as word lines are layered, and a dielectric film 14 is provided between the electrode films. As described above, the end portion of the multilayer body ML22 is shaped like a staircase. As viewed from above, the multilayer body ML22 is located inside the outer edge of the electrode film WL3 of the multilayer body ML21, and the end portion of the multilayer body ML22 and the end portion of the multilayer body ML21 are shaped like a generally continuous staircase.

An etching stopper film 33 is provided above the multilayer body ML22 and the interlayer dielectric film 32 so as to cover them. The etching stopper film 33 is illustratively made of silicon nitride (SiN), and covers also the staircase-shaped end portion of the multilayer body ML22. This covering portion is shaped like a staircase, reflecting the shape of the end portion of the multilayer body ML22, and includes a generally flat portion and a generally vertical portion for each electrode film WL.

An interlayer dielectric film 34 is provided on the etching stopper film 33 immediately above the interlayer dielectric film 32 and immediately above the staircase-shaped portion of the multilayer body ML22, that is, around the multilayer body ML22. The interlayer dielectric film 34 is illustratively formed from BPSG, and the height of the upper surface thereof is generally equal to the height of the upper surface of the etching stopper film 33 immediately above the multilayer body ML22. As described above, the upper select gate USG (see FIGS. 1 and 2) is provided immediately above the multilayer body ML22.

The aforementioned contacts CW, CG, and CD are buried in the interlayer dielectric films 34 and 32 so as to penetrate therethrough in the Z direction. That is, as shown in FIG. 3, the contact CG penetrates through the interlayer dielectric film 34, the etching stopper film 33, the interlayer dielectric film 32, the etching stopper film 31, and the dielectric film 13 and is connected to the upper surface of the lower select gate LSG. The contacts CW0-CW3 penetrate through the interlayer dielectric film 34, the etching stopper film 33, the interlayer dielectric film 32, the etching stopper film 31, and one of the dielectric films 14 and are connected to the upper surface of the electrode films WL0-WL3, respectively. An SiN film 41 is provided between the contacts CW, CG, and CD and the interlayer dielectric film 32.

Furthermore, the contacts CW4-CW7 penetrate through the interlayer dielectric film 34, the etching stopper film 33, and one of the dielectric films 14 and are connected to the upper surface of the electrode films WL4-WL7, respectively. Moreover, at least one of the contacts CD (see FIG. 1) penetrates through the interlayer dielectric film 34, the etching stopper film 33, the interlayer dielectric film 32, the etching stopper film 31, and the interlayer dielectric film 30 and is connected to the cell source CS. Moreover, as described in detail in the second embodiment described later, other contacts CD penetrate through the interlayer dielectric film 34, the etching stopper film 33, the interlayer dielectric film 32, the etching stopper film 31, and the interlayer dielectric film 30 and are connected to transistors formed in the circuit region. The contacts CW0-CW7 (also collectively referred to as “contact CW”), CG, and CD are formed from metal, such as tungsten (W), and a barrier metal layer (not shown) illustratively made of a Ti/TiN bi-layer film is formed on the surface thereof.

Of the aforementioned contacts, the contacts penetrating through the interlayer dielectric film 32, that is, the contacts CW0-CW3, the contact CD, and the contact CG (hereinafter collectively referred to as “high contact”) are each divided into an upper portion formed in the interlayer dielectric film 34 and the etching stopper film 33, and a lower portion formed in the interlayer dielectric film 32 and the layers therebelow. The upper and lower portions of the high contact each have a tapered shape with the diameter decreasing downward. Alternatively, the upper and lower portions of the high contact each have a barrel shape with the upper and lower ends being relatively narrow and the center portion being relatively wide. Thus, a step difference S is formed at the boundary between the upper and lower portions of the high contact. This step difference S is formed at a position in the high contact located between the interlayer dielectric film 32 and the interlayer dielectric film 34, that is, the position located between the multilayer body ML21 and the multilayer body ML22, and is independent of the staircase shape formed at the end portion of the multilayer bodies ML21 and ML22. More specifically, the step difference S is formed at a position in the Z direction corresponding to the boundary between the interlayer dielectric film 32 and the etching stopper film 33.

As shown in FIGS. 4 and 5, the shape of the step difference S is broadly classified into two types. It is noted that in FIGS. 4A and 5A, the side surface at the lower end of the upper portion 36 of the high contact is indicated by a solid line, and the side surface at the upper end of the lower portion 37 of the high contact is indicated by a dashed line. Furthermore, in FIGS. 4B, 4C, 5B, and 5C, the slope of the side surface is emphasized. The upper portion 36 is a portion of the high contact located above the step difference S and located inside the etching stopper film 33 and the interlayer dielectric film 34. The lower portion 37 is a portion of the high contact located below the step difference S and located inside the interlayer dielectric film 32.

In the first type, as shown in FIGS. 4A-4C, as viewed from above (Z direction), the lower end of the upper portion 36 of the high contact is entirely located inside the upper end of the lower portion 37. In the second type, as shown in FIGS. 5A-5C, as viewed from above, the lower end of the upper portion 36 of the high contact is only partly located inside the upper end of the lower portion 37, and the rest of the lower end of the upper portion 36 is located outside the upper end of the lower portion 37. That is, an offset is produced in the second type. The case where the lower end of the upper portion 36 is entirely located outside the upper end of the lower portion 37 is excluded, because the upper portion 36 then fails to communicate with the lower portion 37.

Next, a method for manufacturing a semiconductor memory device according to this embodiment is described.

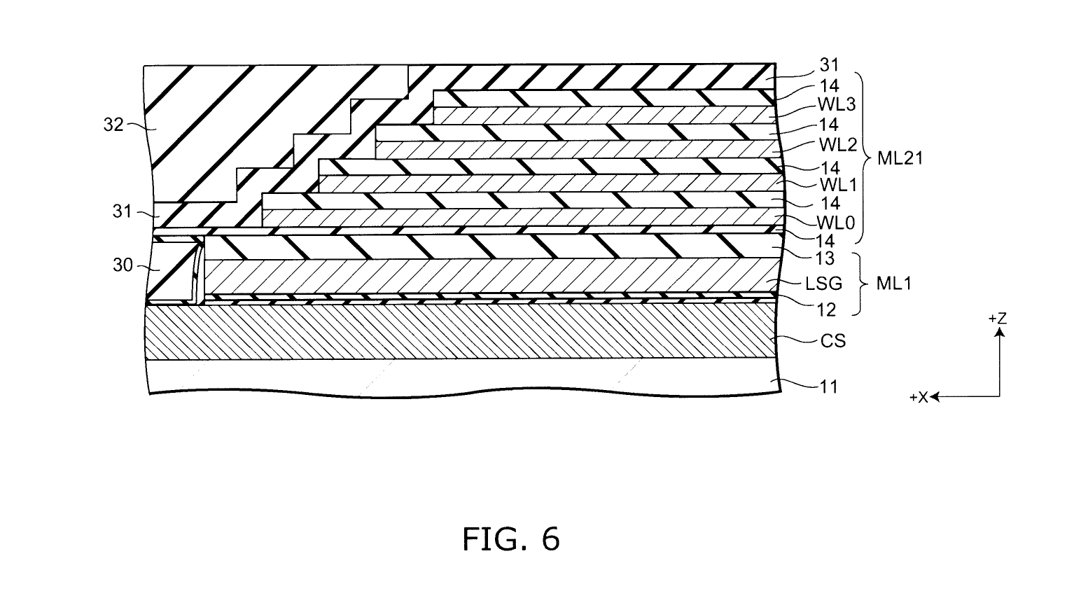

FIGS. 6 to 13 are process cross-sectional views illustrating the method for manufacturing a semiconductor memory device according to this embodiment.

First, as shown in FIGS. 2 and 6, a device isolation film (not shown) is formed at a desired position in the upper portion of a silicon substrate 11. The memory array region is doped with impurities to form a cell source CS. On the other hand, P-wells, N-wells and the like are formed in the circuit region (not shown) to form source regions and drain regions of transistors constituting each driver circuit. Next, gate electrodes of these transistors are formed.

Next, on the silicon substrate 11, a dielectric film 12, a lower select gate LSG, and a dielectric film 13 are formed in this order to form a lower gate multilayer body ML1. Then, through holes 17 are formed in the lower gate multilayer body ML1. A gate dielectric film GD illustratively made of silicon oxide (SiO₂) is formed on the side surface of the through hole 17. Amorphous silicon is buried inside the through hole 17 to form the lower portion of a silicon pillar SP. Thus, a lower select transistor LST is formed. Furthermore, an interlayer dielectric film 30 is formed around the lower gate multilayer body ML1, so that the upper surface of the interlayer dielectric film 30 is generally coplanar with the upper surface of the lower gate multilayer body ML1.

Next, dielectric films 14 and electrode films WL are alternately layered on the lower gate multilayer body ML1 to form a multilayer body ML21. For example, it is formed by repeating the step of forming a dielectric film 14 made of silicon oxide using TEOS (tetraethoxysilane, Si(OC₂H₅)₄), and the step of forming an electrode film WL by depositing amorphous silicon, which is given P⁺-type conductivity by being doped with acceptor such as boron.

Next, through holes 17 are formed in the multilayer body ML21 by lithography and etching so as to communicate with the through holes 17 formed in the lower gate multilayer body ML1. Then, an ONO film 24 is formed by depositing a dielectric layer 25, a charge storage layer 26, and a dielectric layer 27 in this order on the side surface of the through hole 17, and amorphous silicon is buried inside the through hole 17 to form a silicon pillar SP.

Next, a photoresist film (not shown) is formed on the multilayer body ML21 and patterned into a rectangular shape. Then, the end portion of the multilayer body ML21 is processed into a staircase shape by alternately repeating the step of patterning one dielectric film 14 and one electrode film WL by RIE (reactive ion etching) using the photoresist film as a mask, and the step of slightly downsizing (slimming) the outline of the photoresist film by ashing it.

Next, an etching stopper film 31 is formed on the upper and lateral sides of the multilayer body ML21 by entirely depositing e.g. silicon nitride (SiN). The etching stopper film 31 covers the interlayer dielectric film 30 and the multilayer body ML21. Next, BPSG is deposited entirely on the etching stopper film 31. Then, the etching stopper film 31 is used as a stopper to perform CMP (chemical mechanical polishing) for planarization. Thus, BPSG is removed from immediately above the upper surface of the multilayer body ML21, and left only in the region immediately above the interlayer dielectric film 30 and the staircase portion of the multilayer body ML21. Consequently, an interlayer dielectric film 32 made of BPSG is formed around the multilayer body ML21.

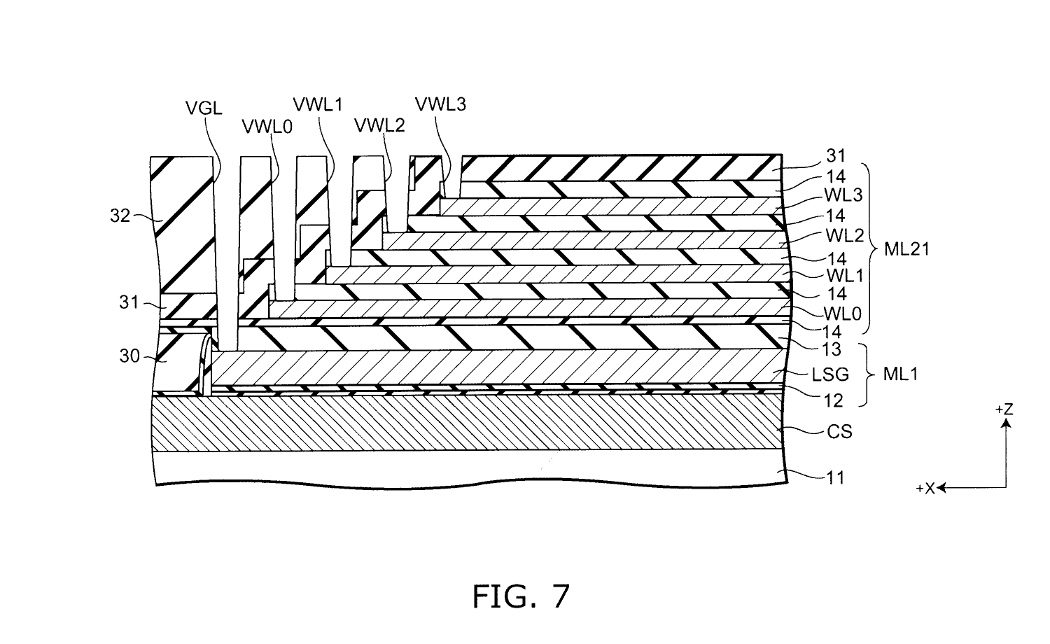

Next, as shown in FIG. 7, RIE is performed on the interlayer dielectric film 32, the etching stopper film 31 and the like to form contact holes VDL (not shown), VGL, VWL0-VWL3. The contact hole VDL penetrates through the interlayer dielectric film 32, the etching stopper film 31, and the interlayer dielectric film 30 and reaches the cell source CS or a transistor formed in the circuit region. The contact hole VGL penetrates through the interlayer dielectric film 32, the etching stopper film 31, and the dielectric film 13 and reaches the lower select gate LSG. The contact holes VWL0-VWL3 penetrate through the interlayer dielectric film 32, the etching stopper film 31, and one of the dielectric films 14 and reach the electrode films WL0-WL3, respectively.

Here, the side surface of each contact hole has no discontinuity such as step difference, but is formed as a continuous surface. For example, each contact hole has a tapered shape in which the diameter is maximized at the upper end, decreased downward, and minimized at the lower end. In this case, the side surface of each contact hole is inclined with respect to the Z direction. Alternatively, each contact hole has a barrel shape in which the center portion has a larger diameter than the upper and lower ends. In this case, the side surface of each contact hole is curved convex outward.

In this etching, the etching stopper film 31 serves as a stopper. More specifically, first, etching is performed under the condition that BPSG is etched and silicon nitride (SiN) is not etched, to form the contact holes to a depth reaching the etching stopper film 31. This results in contact holes (sub-holes) with the etching stopper film 31 exposed to the bottom surface thereof. Thus, the remaining thickness to the final target depth of the contact hole is made nearly equal between the contact holes. Next, etching is performed under the condition that SiN is etched, to simultaneously process the etching stopper film 31 exposed to the bottom surface of the contact holes (sub-holes). Thus, the processing can be performed by accurately controlling the etching amount.

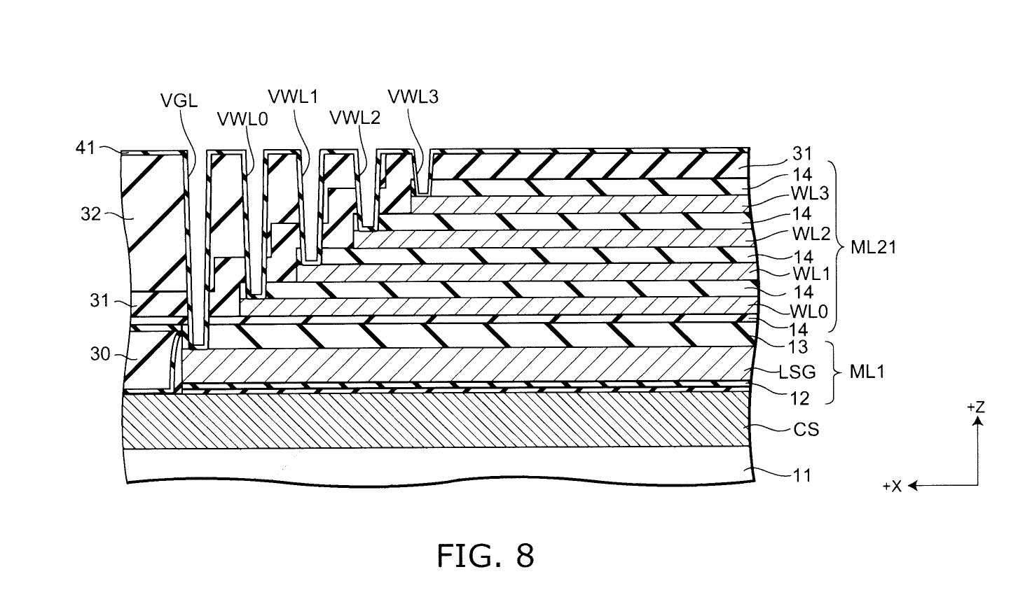

Next, as shown in FIG. 8, silicon nitride (SiN) is entirely deposited to form an SiN film 41. This SiN film 41 is formed not only on the upper surface of the interlayer dielectric film 32 and the upper surface of the exposed portion of the etching stopper film 31, but also on the side surface and bottom surface of each contact hole.

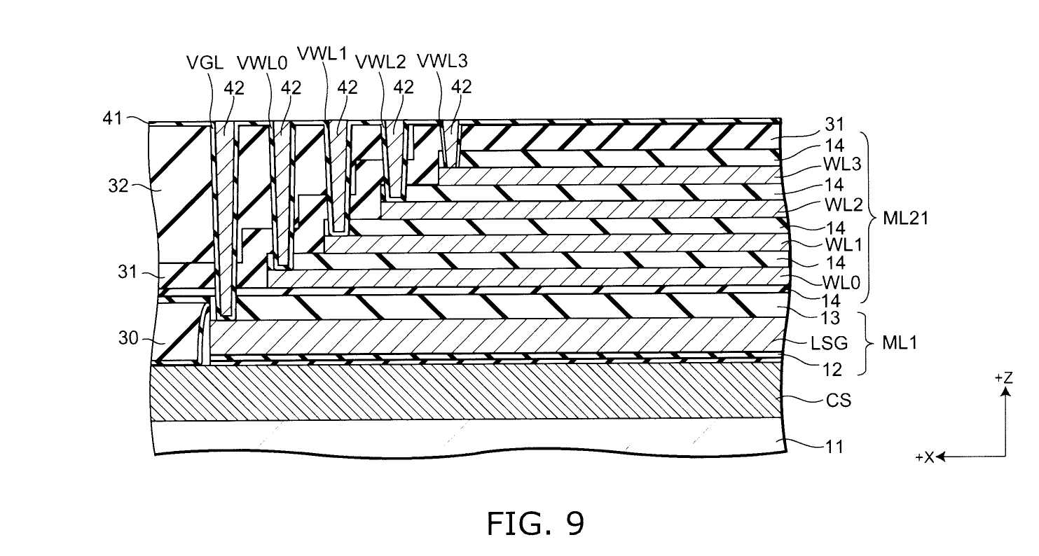

Next, as shown in FIG. 9, non-doped amorphous silicon is entirely deposited. Next, this amorphous silicon is recessed to remove the amorphous silicon from above the upper surface of the interlayer dielectric film 32 and the upper surface of the etching stopper film 31, and is left only inside each contact hole. Thus, a sacrificial material 42 made of non-doped amorphous silicon is buried in each contact hole.

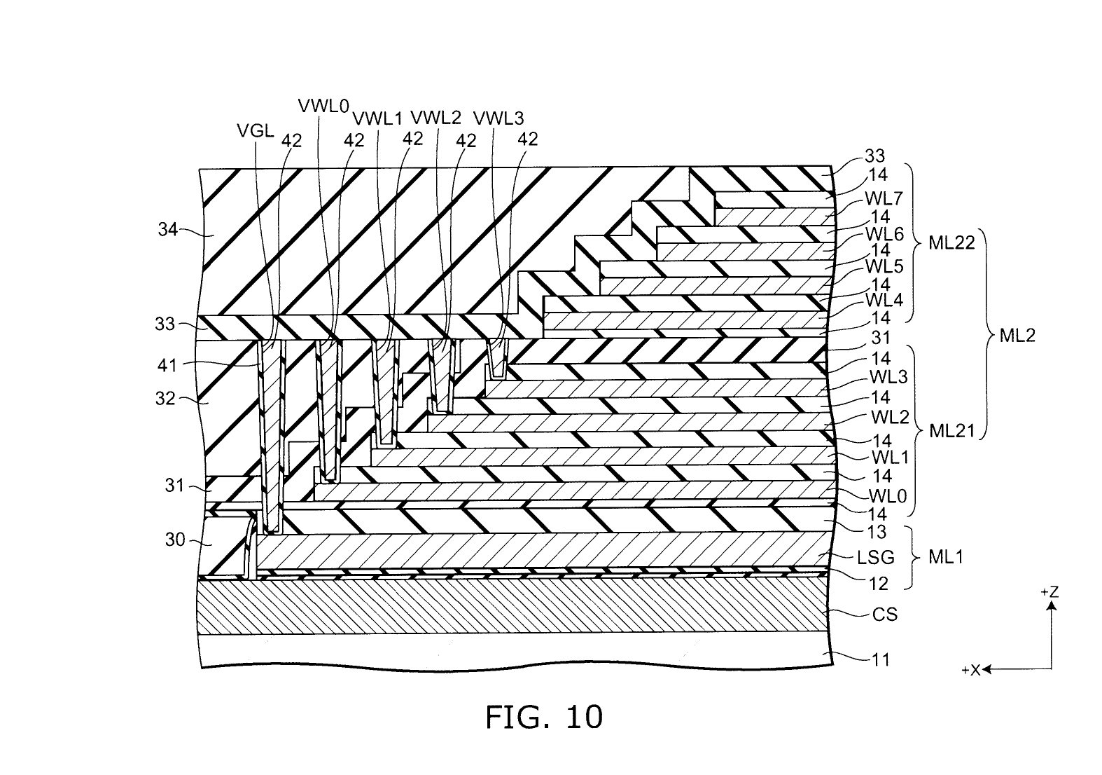

Next, as shown in FIG. 10, a method similar to the aforementioned method of forming the multilayer body ML21, the etching stopper film 31, and the interlayer dielectric film 32 is used to form a multilayer body ML22 on the etching stopper film 31 immediately above the upper surface of the multilayer body ML21 and process the end portion of the multilayer body ML22 into a staircase shape. The multilayer body ML21 and the multilayer body ML22 constitute a memory multilayer body ML2.

Next, an etching stopper film 33 made of SiN is formed so as to cover the interlayer dielectric film 32 and the multilayer body ML22, BPSG is deposited, and the etching stopper film 33 is used as a stopper to perform CMP. Thus, an interlayer dielectric film 34 made of BPSG is formed around the multilayer body ML22.

Here, four electrode films WL4-WL7 illustratively made of P-type amorphous silicon are layered in the multilayer body ML22. Then, as shown in FIG. 2, through holes 17 are formed in the multilayer body ML22, an ONO film 24 is formed by depositing a dielectric layer 25, a charge storage layer 26, and a dielectric layer 27 in this order on the side surface of the through hole 17, and amorphous silicon is buried inside the through hole 17 to form a silicon pillar SP. Thus, the silicon pillar in the multilayer body ML21 and the silicon pillar in the multilayer body ML22 are connected, forming the center portion of the silicon pillar SP.

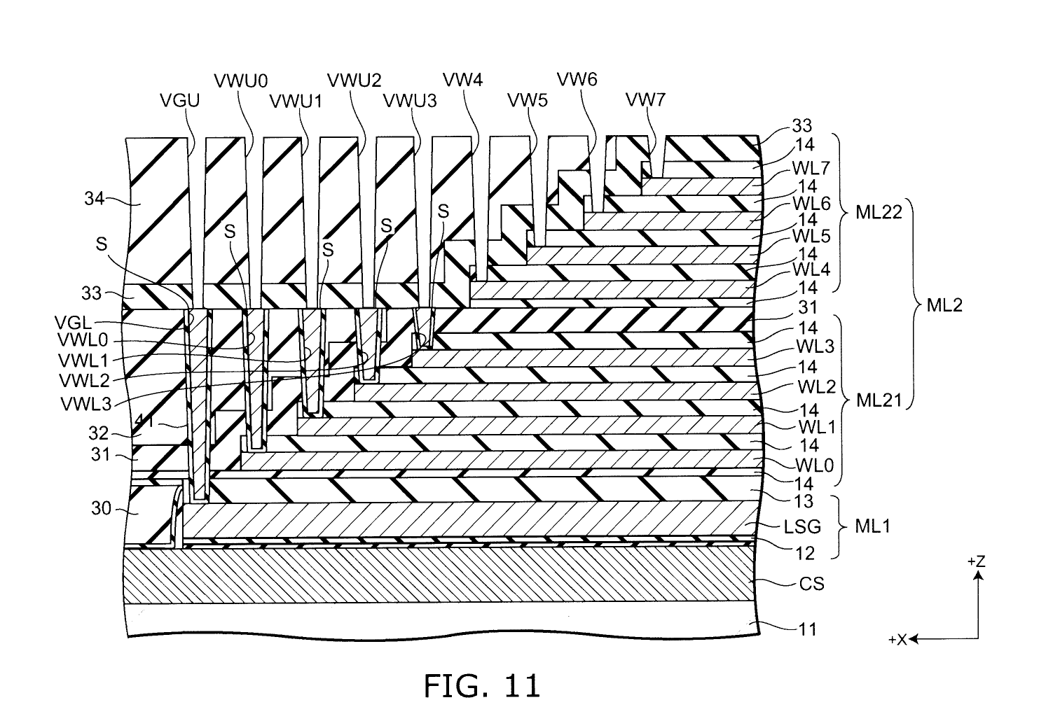

Next, as shown in FIG. 11, RIE is performed on the interlayer dielectric film 34 and the etching stopper film 33 to form contact holes VDU (not shown), VGU, VWU0-VWU3, and VW4-VW7. Here, the etching stopper film 33 serves as a stopper. More specifically, BPSG is etched to form sub-holes to a depth reaching the etching stopper film 33. Subsequently, the etching stopper film 33 exposed to the bottom surface of these sub-holes is etched so that the etching stopper film 33 is penetrated. Each contact hole has a tapered shape in which the diameter is maximized at the upper end, decreased downward, and minimized at the lower end, like the aforementioned contact hole formed in the interlayer dielectric film 32. Hence, each contact hole has a continuous side surface, which is inclined with respect to the Z direction.

If any contact hole formed in the interlayer dielectric film 32 is located immediately below the contact hole formed in the interlayer dielectric film 34, the latter communicates with the former to form one continuous contact hole. That is, the contact hole VDU (not shown) is formed immediately above the contact hole VDL (not shown) formed in the interlayer dielectric film 32 by the process shown in FIG. 7 so as to reach it and communicate therewith. Likewise, the contact hole VGU is formed immediately above the contact hole VGL so as to reach it and communicate therewith. The contact holes VWU0-VWU3 are formed immediately above the contact holes VWL0-VWL3, respectively, so as to reach them and communicate therewith.

In such a high contact hole in which the contact hole formed in the interlayer dielectric film 32 and the contact hole formed in the interlayer dielectric film 34 are in communication with each other, a step difference S having a shape as shown in FIGS. 4 and 5 is formed at the boundary therebetween.

On the other hand, of the contact holes formed in the interlayer dielectric film 34, the holes with no contact hole formed therebelow in the interlayer dielectric film 32 directly reach the end portion of the electrode films in the multilayer body ML22. That is, the contact holes VW4-VW7 reach the end portion of the electrode films WL4-WL7, respectively.

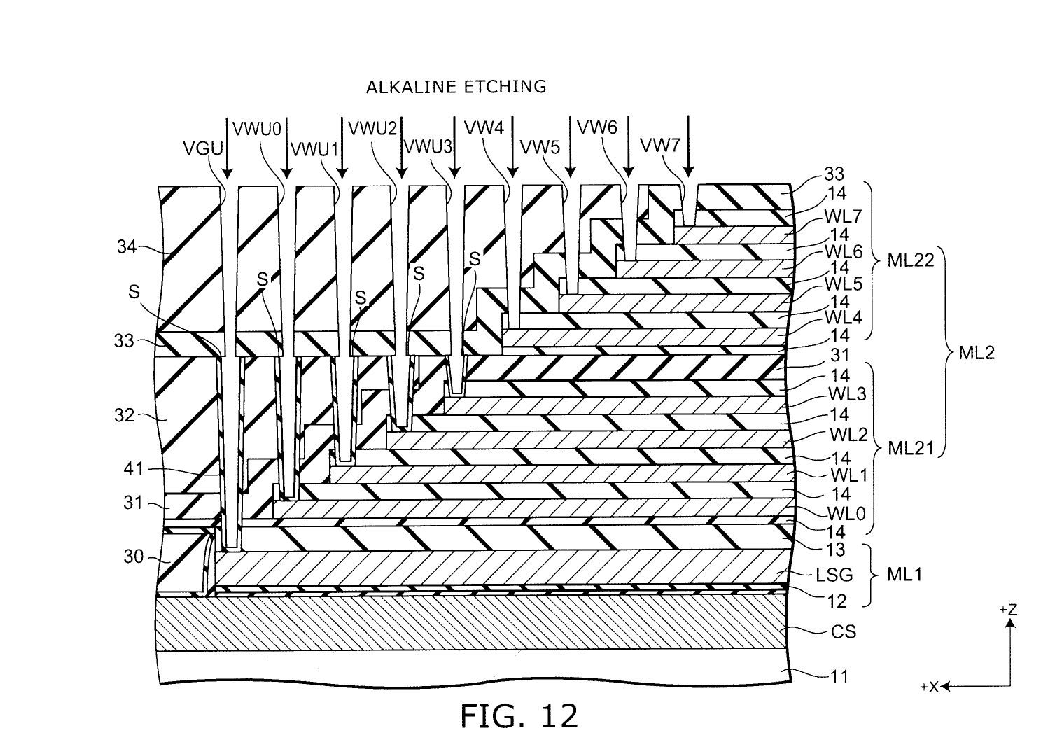

Next, as shown in FIG. 12, alkaline etchant is used to perform wet etching (alkaline etching) to remove the sacrificial material 42 (see FIG. 11) buried in each contact hole. In this alkaline etching, non-doped silicon is etched, but silicon given P⁺-type conductivity by being doped with acceptor such as boron is not etched. Hence, the sacrificial material 42 is removed, but the electrode films WL and the lower select gate LSG are not removed. Furthermore, the silicon substrate 11 located at the bottom surface of the contact hole VDL (not shown) is not etched because it is covered with the SiN film 41. Thus, it is possible to selectively remove only the sacrificial material 42 made of non-doped amorphous silicon.

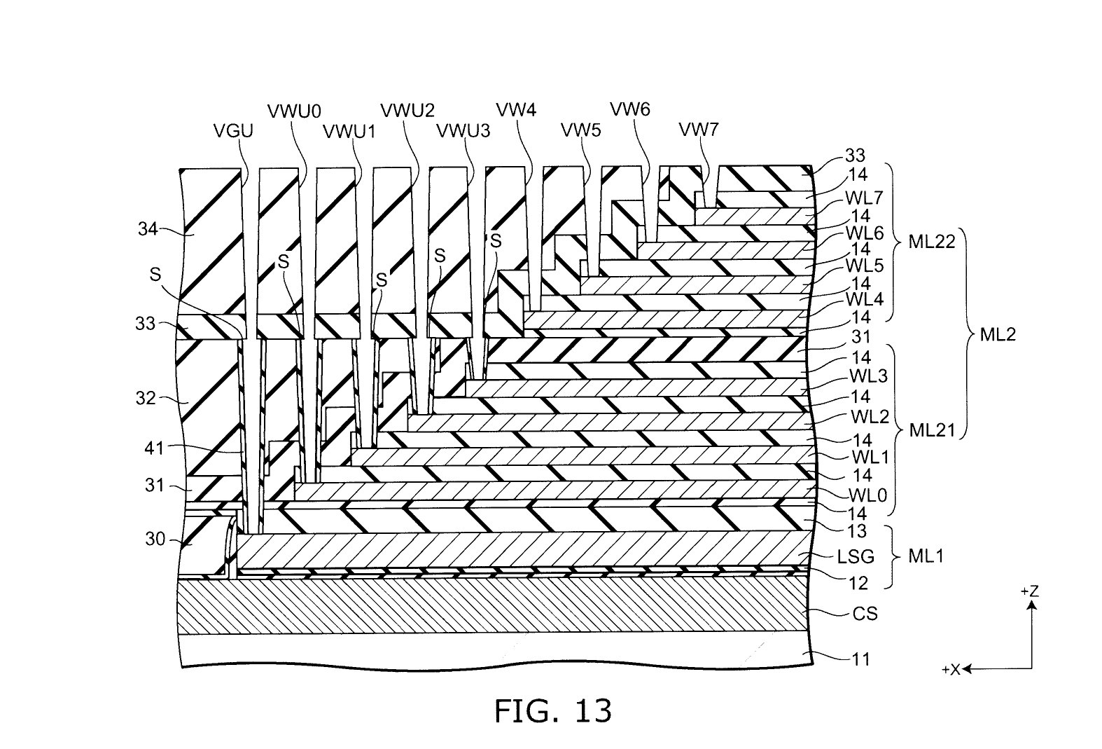

Next, as shown in FIG. 13, RIE or the like is performed to remove the SiN film 41 from above the bottom surface of each contact hole.

Next, as shown in FIG. 3, titanium nitride (TiN) and titanium (Ti) are deposited to form a barrier metal layer (not shown) made of a Ti/TiN bi-layer film on the inner surface of each contact hole. Next, tungsten (W) is entirely deposited. Then, planarization is performed by CMP so that tungsten is removed from above the upper surface of the interlayer dielectric film 34 and the upper surface of the multilayer body ML22, and left only inside each contact hole. Thus, contacts CD, CG, CW0-CW7 made of tungsten are buried inside the contact holes.

Subsequently, on the etching stopper film 33 immediately above the multilayer body ML22, as shown in FIG. 2, a dielectric film 15, an upper select gate USG, and a dielectric film 16 are formed in this order to form a multilayer body ML3. Then, through holes 17 are formed in the multilayer body ML3, a gate dielectric film GD is formed on the side surface thereof, and the upper portion of the silicon pillar SP is buried inside the through hole 17. Next, a dielectric film 18 is formed on the multilayer body ML3.

Next, as shown in FIG. 1, a metal film is entirely formed and patterned into bit interconnects BL, upper select gate interconnects USL, word interconnects WLL, a lower select gate interconnect LSL, and a cell source interconnect CSL. Here, each word interconnect WLL is connected to an associated contact CW, the lower select gate interconnect LSL is connected to the contact CG, and the cell source interconnect CSL is connected to part of the contacts CD. Thus, the semiconductor memory device 1 according to this embodiment is manufactured.

Next, the operation and effect of this embodiment are described.

In this embodiment, the memory multilayer body ML2 including three-dimensionally integrated memory cells has a two-stage configuration composed of the multilayer body ML21 and the multilayer body ML22, and the contact holes of the lower multilayer body ML21 reaching the electrode films WL are formed in two steps, one for each multilayer body. This decreases the difficulty of processing by reducing the aspect ratio of the contact hole formed in one step, while as a whole, a contact hole having a high aspect ratio can be formed. Thus, the total number of layered electrode films can be increased. Consequently, according to this embodiment, a three-dimensional multilayer semiconductor memory device having a large number of layered films can be manufactured.

Furthermore, in this embodiment, the lower portion of the contact hole formed in the interlayer dielectric film 32 is once filled with a sacrificial material 42, an upper structure including an interlayer dielectric film 34 is formed thereon, and the upper portion of the contact hole is formed in the interlayer dielectric film 34. Then, the sacrificial material buried in the lower portion of the contact hole is removed through the upper portion thereof to form a contact hole having a high aspect ratio where the lower portion is in communication with the upper portion. Thus, the lower portion of the contact hole once formed is not refilled with the interlayer dielectric film 34 formed subsequently.

The two-stage configuration of the memory multilayer body ML2 with contact holes formed in two steps requires a slightly larger number of processes than one-stage configuration of the memory multilayer body ML2 with contact holes formed in one step. However, by increasing the number of layered films, the chip area per bit is reduced, and a larger number of semiconductor memory devices 1 can be fabricated from one wafer. Thus, as a whole, the manufacturing cost of the semiconductor memory device 1 can be significantly reduced.

In this embodiment, by way of example, the memory multilayer body ML2 has a two-stage configuration composed of the multilayer body ML21 and the multilayer body ML22, and four electrode films are layered in each of the multilayer body ML21 and the multilayer body ML22. However, the invention is not limited thereto. That is, the memory multilayer body including memory cells may have three or more stages of multilayer bodies, and the multilayer body of each stage may include five or more electrode films. For example, ten to twenty electrode films may be layered in the multilayer body of each stage. Also in this case, a step differences is formed at a position in the contact located between interlayer dielectric films, the contact connecting the upper metal interconnect (word interconnect WLL) to the electrode film of a multilayer body in the memory multilayer body at other than the uppermost stage. That is, in the case where the memory multilayer body has n stages of multilayer bodies (where n is an integer of two or more), the contact connected to the electrode film of the k-th lowest multilayer body has step differences at (n−k) positions (where k is an integer of 1 to n−1).

Next, a second embodiment of the invention is described.

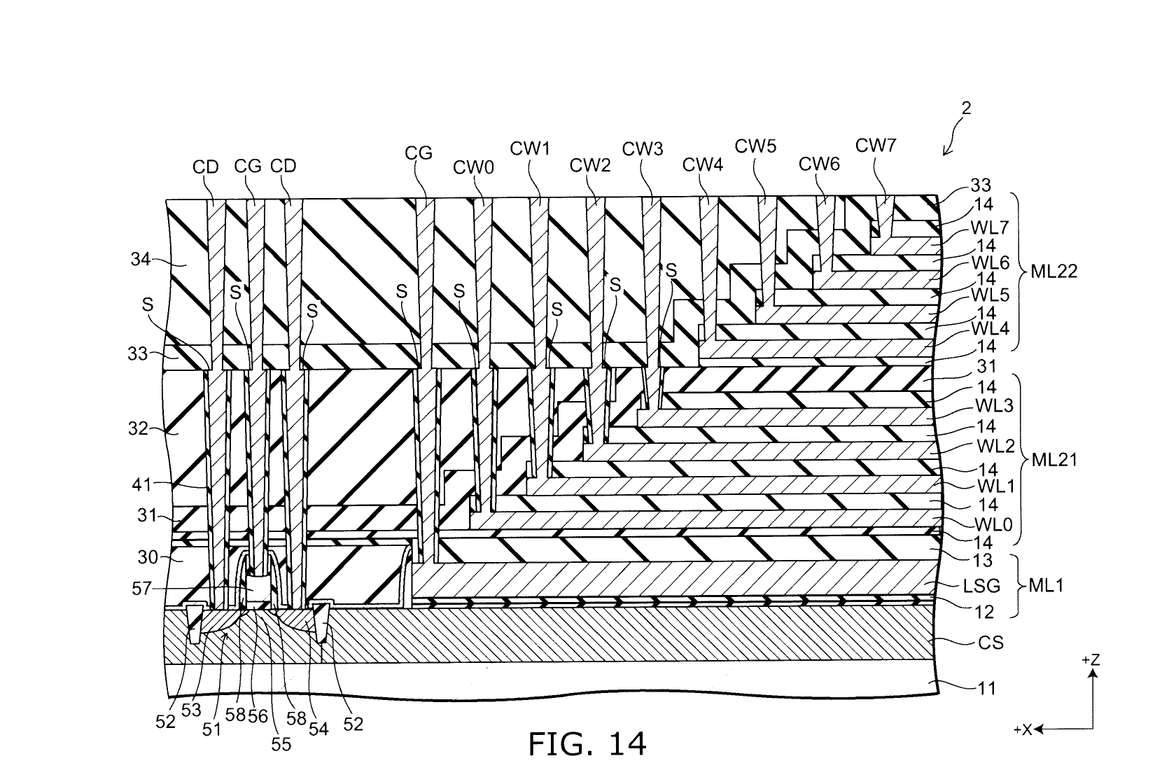

FIG. 14 is a cross-sectional view illustrating the semiconductor memory device according to this embodiment.

As shown in FIG. 14, in the semiconductor memory device 2 (hereinafter also simply referred to as “device 2”) according to this embodiment, the electrode films WL0-WL7 serving as word lines, the lower select gate LSG, and the contacts CW0-CW7 and the contact CG are formed from the same conductive material including metal, such as aluminum (Al) containing several % silicon (Si). The electrode films and the lower select gate are formed integrally with the contacts without a barrier metal layer interposed therebetween.

FIG. 14 also shows a transistor 51 formed in the circuit region of the device 2. In the transistor 51, a source region 53 and a drain region 54, spaced from each other, are formed in a region partitioned by a device isolation film 52 in the upper portion of the silicon substrate 11, and the region between the source region 53 and the drain region 54 constitutes a channel region 55. A gate dielectric film 56 is formed on the channel region 55, a gate electrode 57 is provided thereon, and a sidewall 58 is provided on the side surface thereof.

Furthermore, a contact CD is connected to each of the source region 53 and the drain region 54, and a contact CG is connected to the gate electrode 57. The gate electrode 57 and the contact CG are also formed from a conductive material including metal, such as aluminum (Al) containing several % silicon (Si). On the other hand, the contacts CD connected to the source region 53 and the drain region 54 are formed from metal, such as tungsten (W), as in the above first embodiment.

The configuration of this embodiment other than the foregoing is the same as that of the above first embodiment. That is, the memory multilayer body ML2 has two stages of multilayer bodies ML21 and ML22, and a step difference S is formed in the contacts CW connected to the electrode films WL of the lower multilayer body ML21 and the contact CG connected to the lower select gate LSG.

Next, a method for manufacturing a semiconductor memory device according to this embodiment is described.

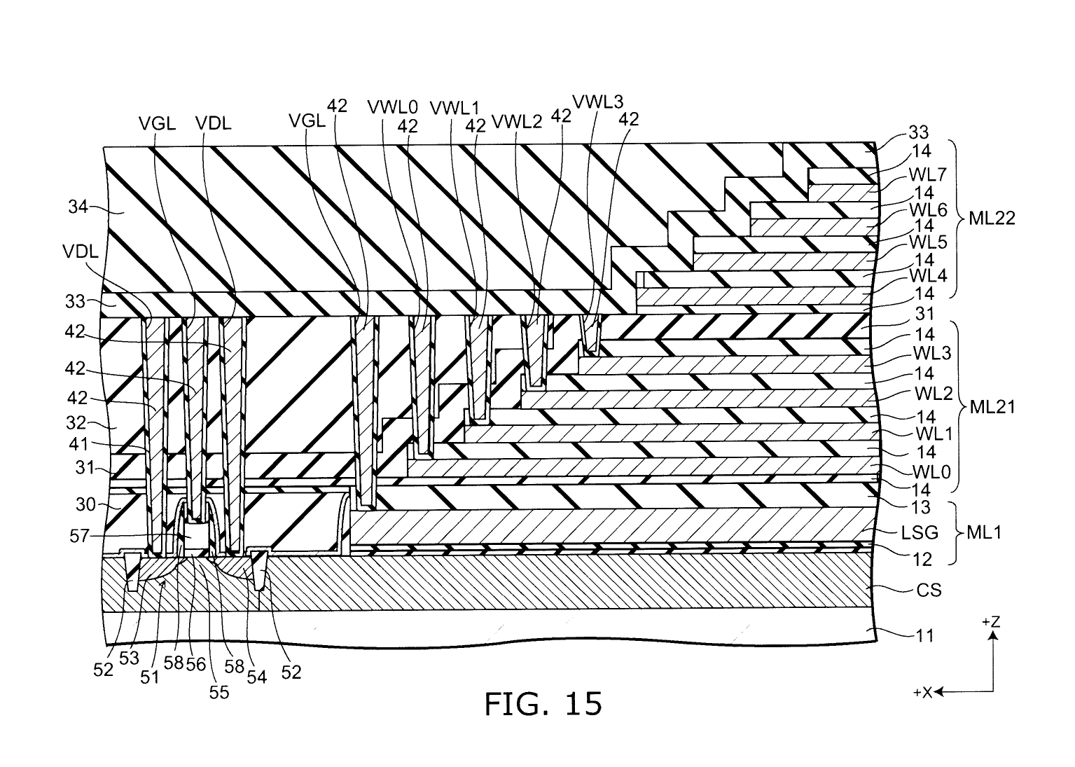

FIGS. 15 to 24 are process cross-sectional views illustrating the method for manufacturing a semiconductor memory device according to this embodiment.

First, the process in the above first embodiment shown in FIGS. 6 to 10 is performed to fabricate an intermediate structure shown in FIG. 15. In this intermediate structure, contact holes are formed in the lower interlayer dielectric film 32, and a sacrificial material 42 made of non-doped amorphous silicon is buried in each contact hole. On the other hand, a transistor 51 is formed in the circuit region by conventional methods.

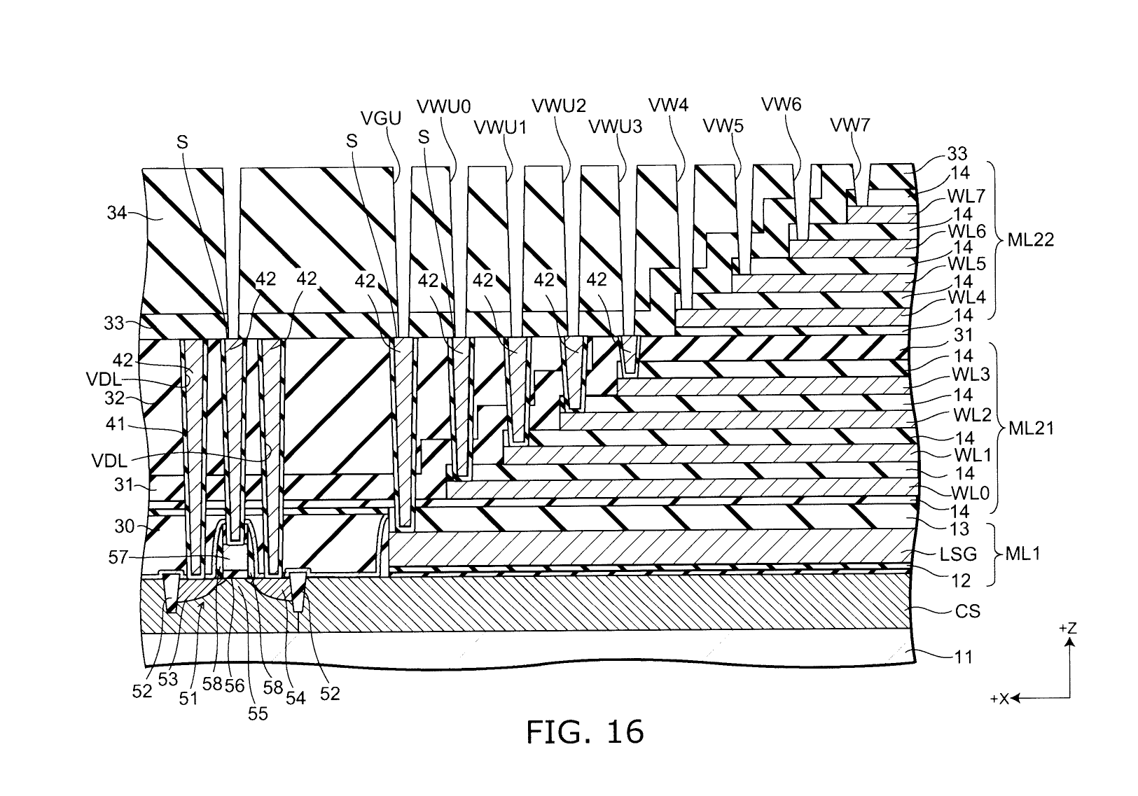

Next, as shown in FIG. 16, a process similar to that shown in FIG. 11 is performed to form contact holes in the interlayer dielectric film 34. This allows the contact hole formed in the interlayer dielectric film 34 to communicate with the contact hole formed in the interlayer dielectric film 32 and produces a step difference S at the joint therebetween. At this stage, no contact hole is formed immediately above the contact holes VDL that have already reached the source region 53 and the drain region 54 of the transistor 51.

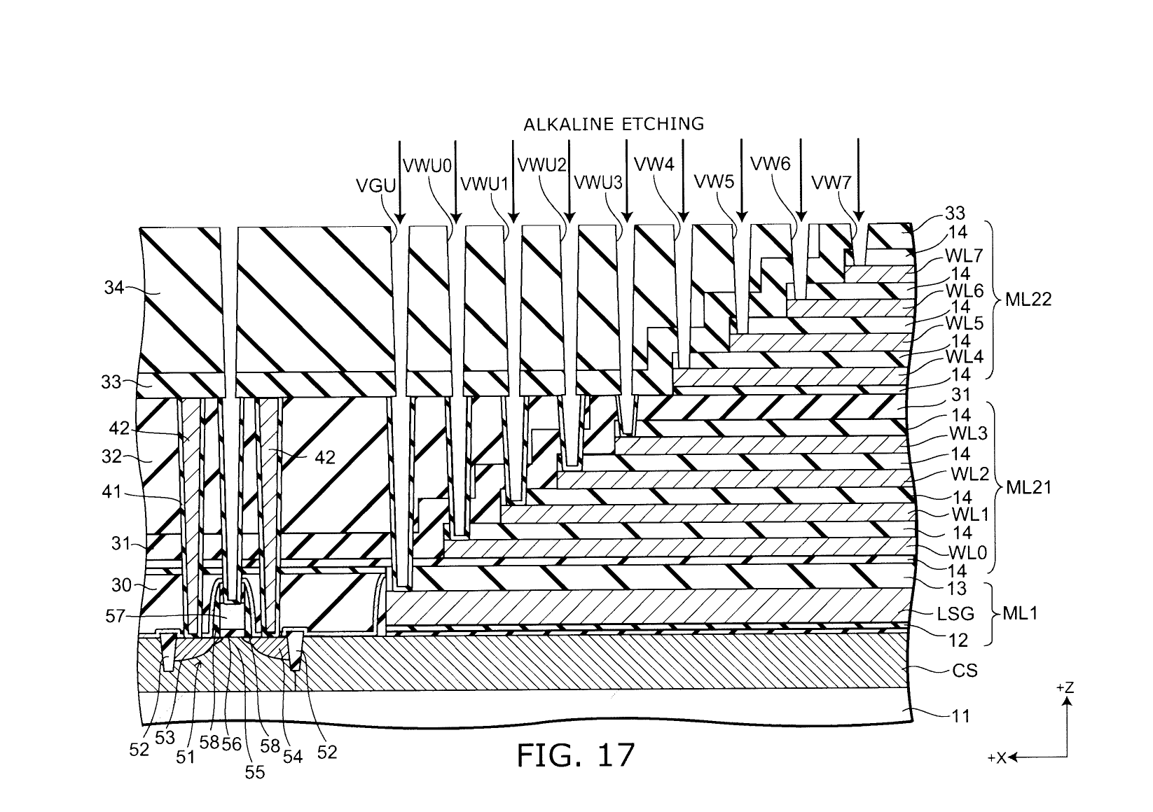

Next, as shown in FIG. 17, like the process shown in FIG. 12, alkaline etchant is used to perform wet etching (alkaline etching) to remove the sacrificial material 42 from inside the contact holes opening upward, that is, the contact holes other than the contact holes VDL. At this time, the sacrificial material 42 made of non-doped amorphous silicon is etched, but the electrode films WL, the lower select gate LSG, and the gate electrode 57 made of P-type amorphous silicon are not etched.

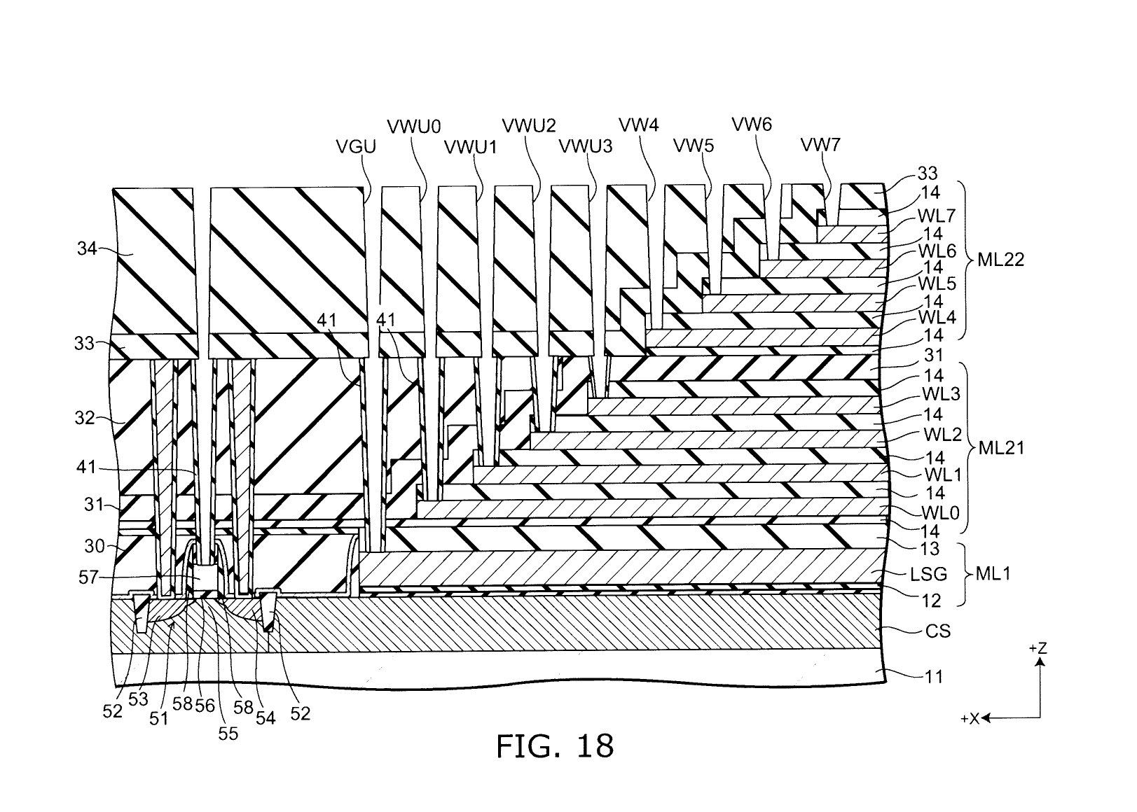

Next, as shown in FIG. 18, like the process shown in FIG. 13, RIE or the like is performed to remove the SiN film 41 from above the bottom surface of each contact hole.

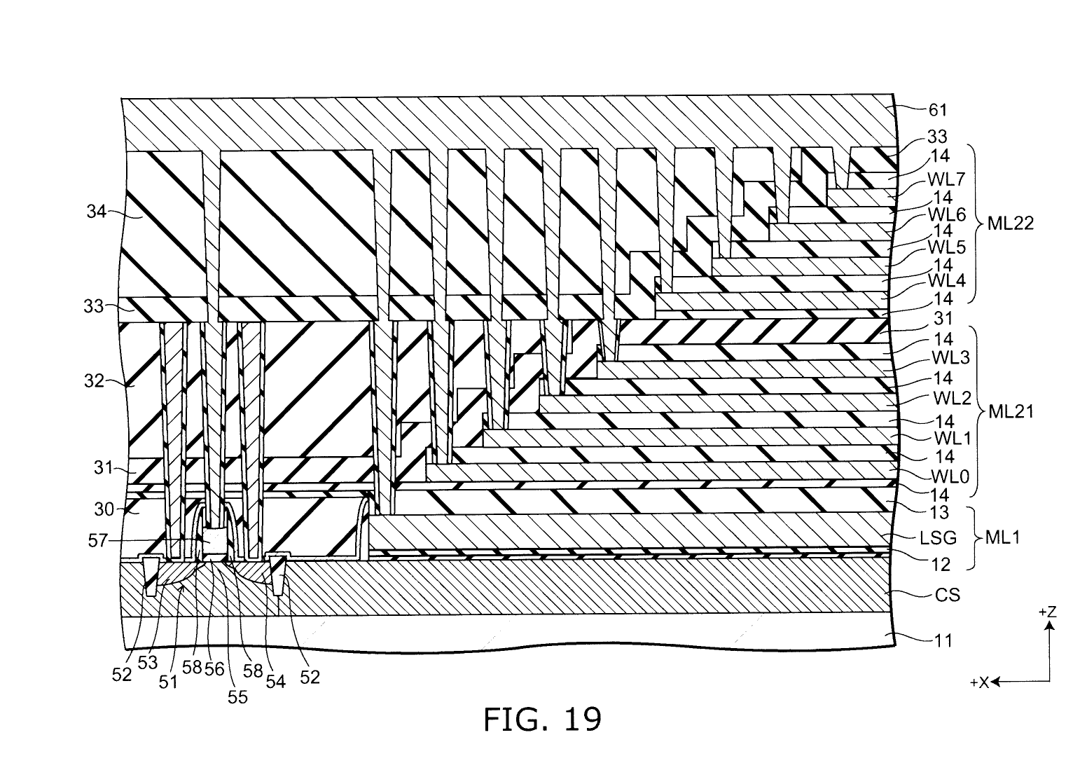

Next, as shown in FIG. 19, aluminum (Al) is entirely deposited to form an aluminum film 61. Here, the aluminum film 61 is deposited not only on the upper surface of the interlayer dielectric film 34 and the upper surface of the multilayer body ML22, but also inside each contact hole, and is in contact with the gate electrode 57 of the transistor 51, the lower select gate LSG, and the electrode films WL0-WL7 of the memory multilayer body ML2.

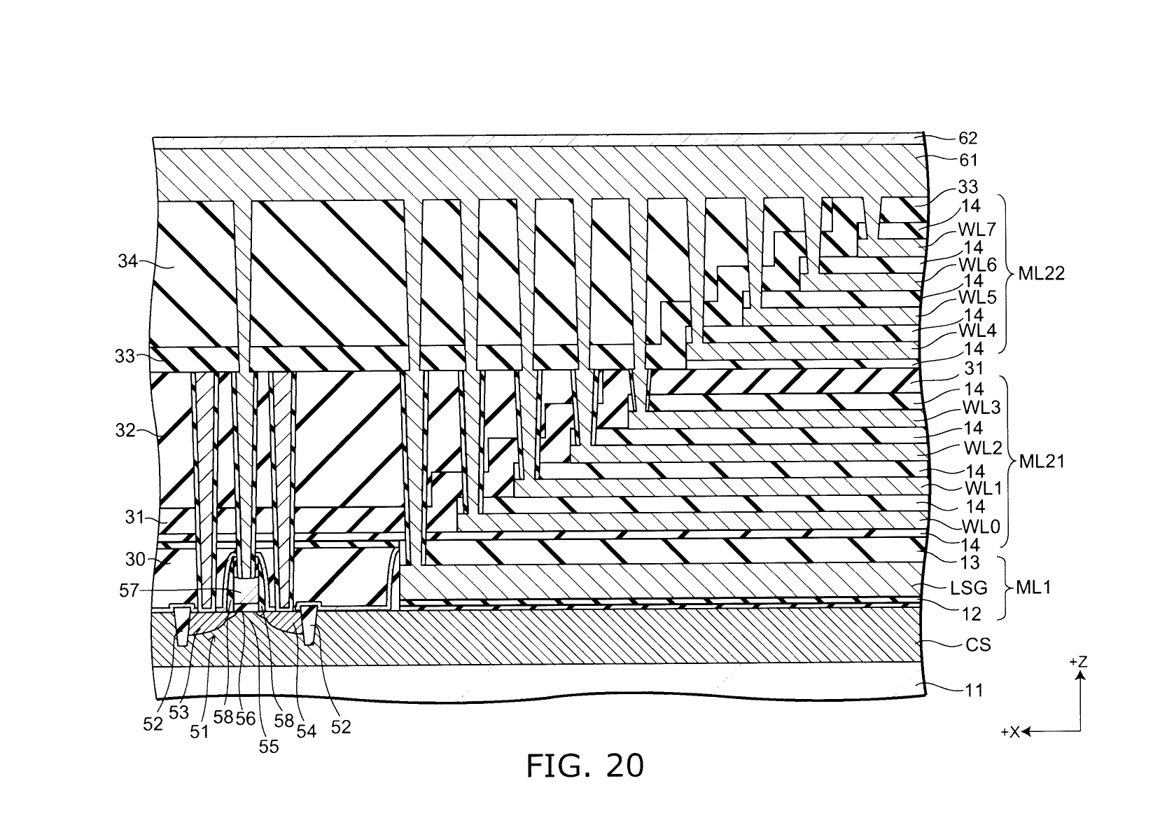

Next, as shown in FIG. 20, heat treatment is performed, for example, at a temperature of 400° C. or more for a desired time. This allows aluminum and silicon to diffuse into each other so that silicon contained in the gate electrode 57, the lower select gate LSG, and the electrode films WL0-WL7 is at least partly replaced by aluminum contained in the aluminum film 61. Consequently, the material forming the gate electrode 57, the lower select gate LSG, and the electrode films WL0-WL7 is turned into aluminum (Al) containing several % silicon (Si) and constitutes a metal gate. Furthermore, aluminum (Al) containing several % silicon (Si) is buried in the contact holes except the contact holes VDL to form contacts made of silicon-containing aluminum. On the other hand, above the interlayer dielectric film 34 and the multilayer body ML22, a silicon layer 62 is formed on the upper surface of the aluminum film 61.

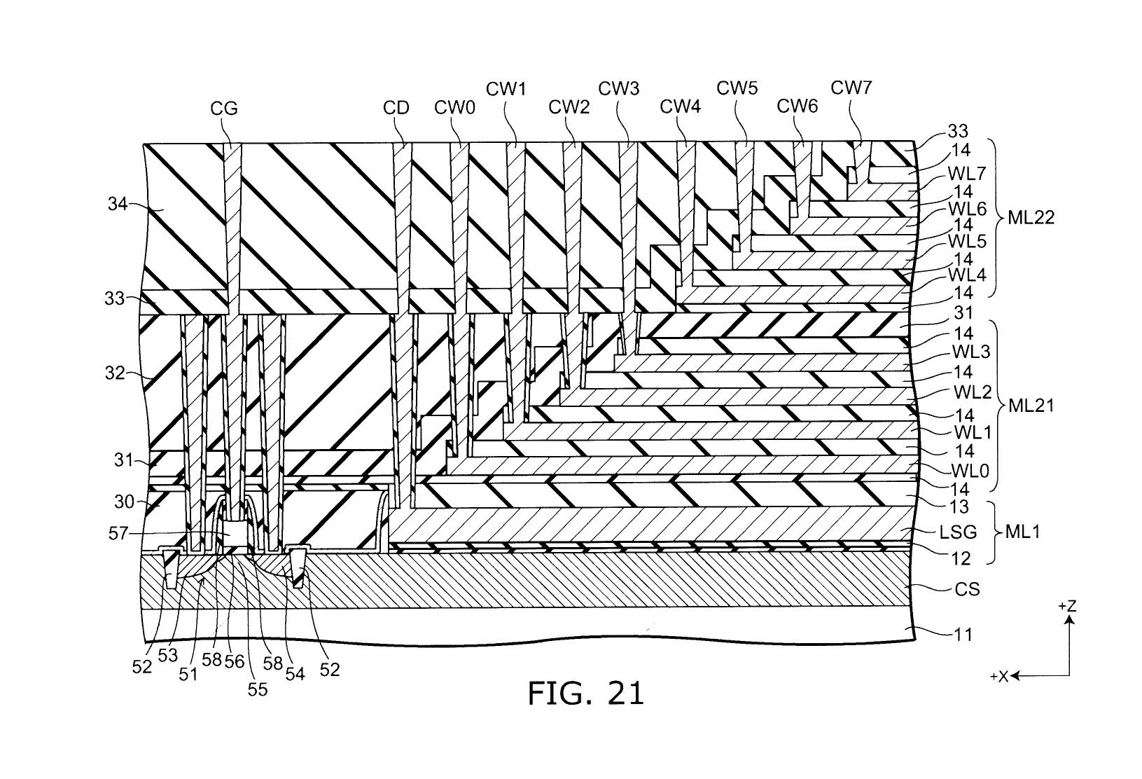

Next, as shown in FIG. 21, the aluminum film 61 is recessed by RIE so that the aluminum film 61 deposited on the upper surface of the interlayer dielectric film 34 and the upper surface of the multilayer body ML22 is removed together with the silicon layer 62.

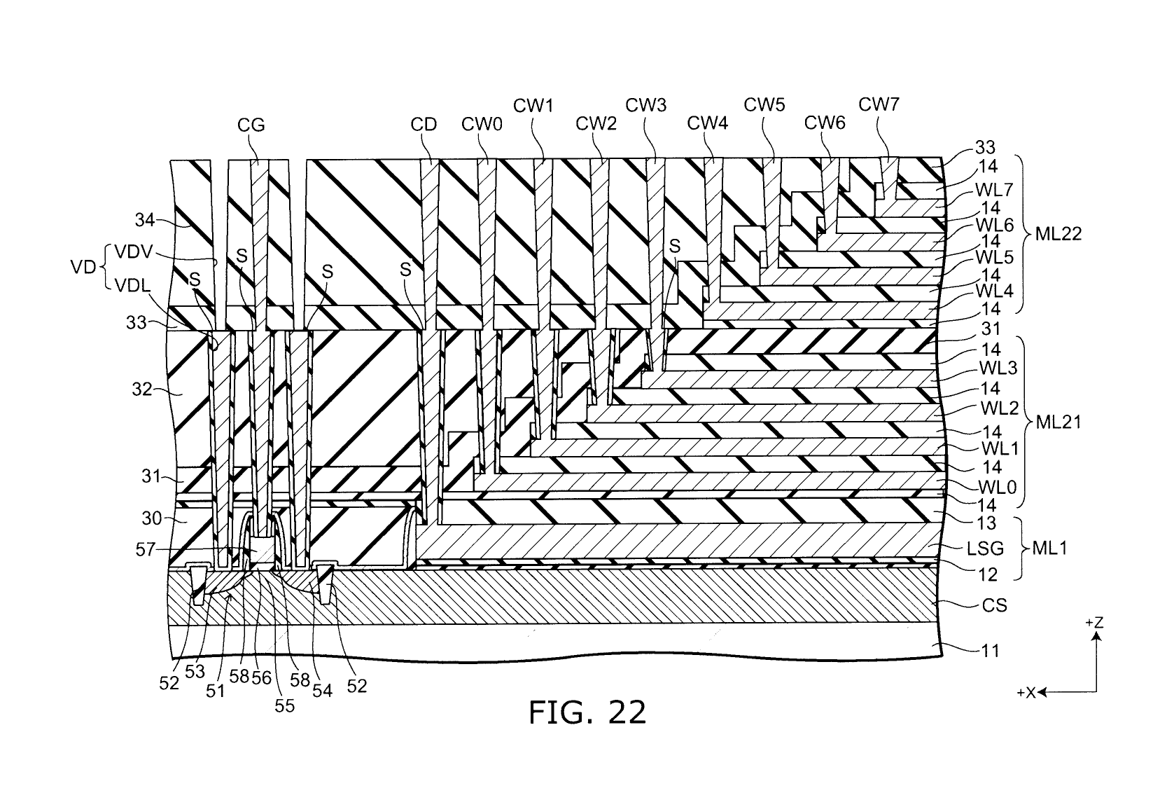

Next, as shown in FIG. 22, a contact hole VDU is formed immediately above the contact hole VDL in the interlayer dielectric film 34. Thus, the contact hole VDU communicates with the contact hole VDL to constitute one contact hole VD. A step difference S is formed at the boundary between the contact hole VDU and the contact hole VDL.

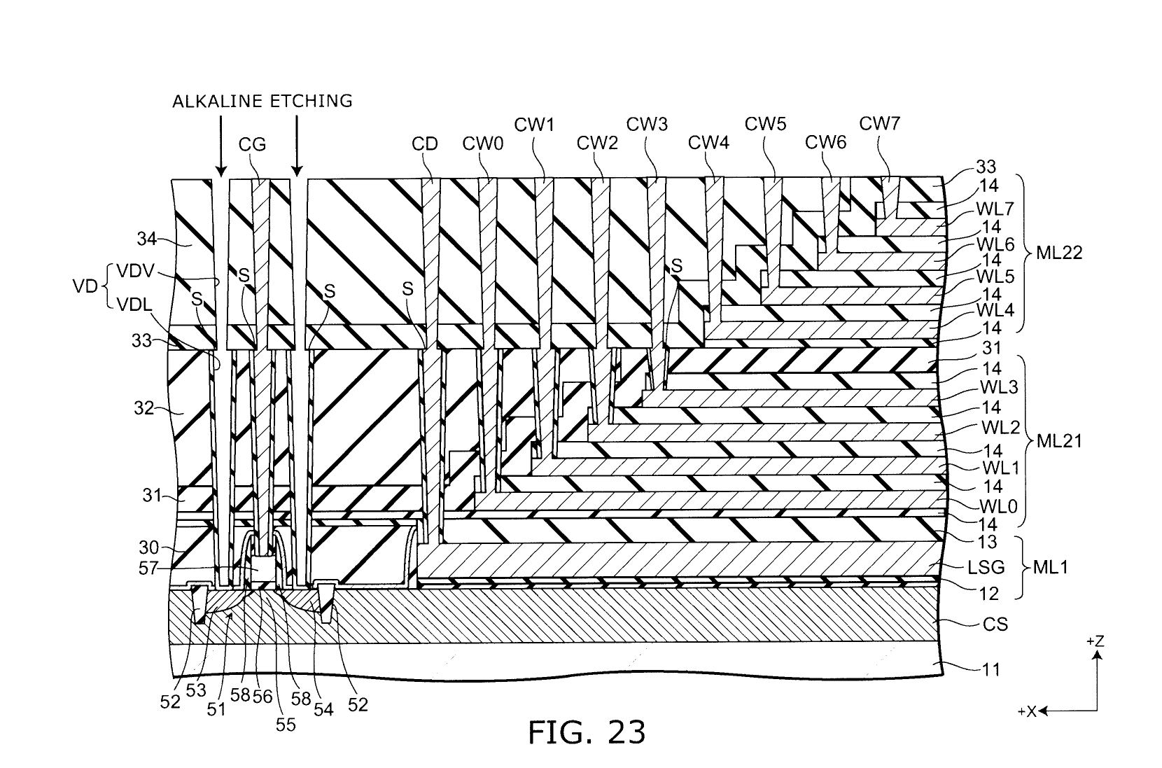

Next, as shown in FIG. 23, alkaline etching is performed to remove the sacrificial material 42 buried inside the contact hole VDL. At this time, the silicon substrate 11 is not etched because the bottom surface of the contact hole VDL is covered with the SiN film 41.

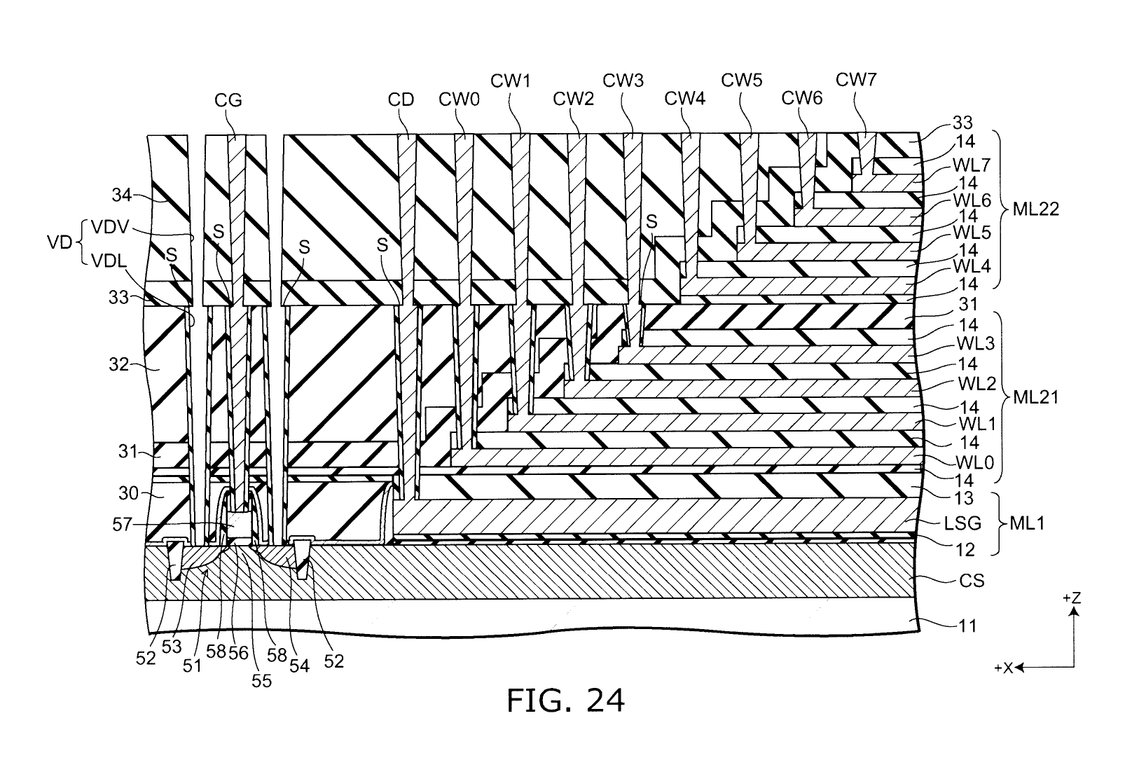

Next, as shown in FIG. 24, RIE or the like is performed to remove the SiN film 41 from above the bottom surface of the contact hole VDL.

Next, as shown in FIG. 14, titanium nitride (TiN) and titanium (Ti) are deposited to form a barrier metal layer (not shown) made of a Ti/TiN bi-layer film on the inner surface of the contact hole VD. Next, tungsten (W) is entirely deposited. Then, planarization is performed by CMP so that tungsten is removed from above the upper surface of the interlayer dielectric film 34 and the upper surface of the multilayer body ML22, and left only inside the contact hole VD. Thus, a contact CD is buried inside the contact hole VD.

Subsequently, a method similar to that of the above first embodiment is used to form an upper gate multilayer body ML3, upper interconnects and the like. Thus, the semiconductor memory device 2 according to this embodiment is manufactured. The manufacturing method of this embodiment other than the foregoing is the same as that of the above first embodiment.

Next, the operation and effect of this embodiment are described.

In this embodiment, in addition to the operation and effect of the above first embodiment, the gate electrode 57, the lower select gate LSG, and the electrode films WL0-WL7 can be made of metal gates. Thus, the resistance of these conductor layers can be reduced. The operation and effect of this embodiment other than the foregoing are the same as those of the above first embodiment.

Next, a third embodiment of the invention is described.

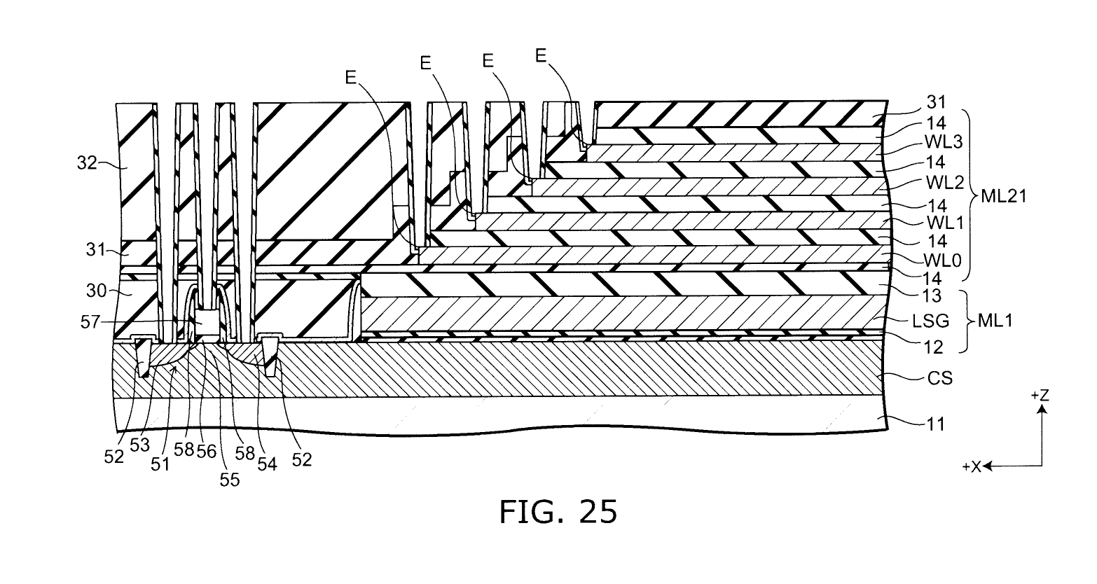

FIG. 25 is a process cross-sectional view illustrating a method for manufacturing a semiconductor memory device according to this embodiment.

As shown in FIG. 25, in this embodiment, in the step of forming contact holes VWL0-VWL3 and the like in the interlayer dielectric film 32 and the etching stopper film 31 shown in FIG. 7, at least one of the contact holes VWL0-VWL3 is allowed to reach the edge E between the upper surface and the side surface of the electrode film WL. Thus, in the completed semiconductor memory device, at least one of the contacts CW is in contact with the edge E of the electrode film. The configuration and the manufacturing method of this embodiment other than the foregoing are the same as those of the above first embodiment.

Next, the operation and effect of this embodiment are described.

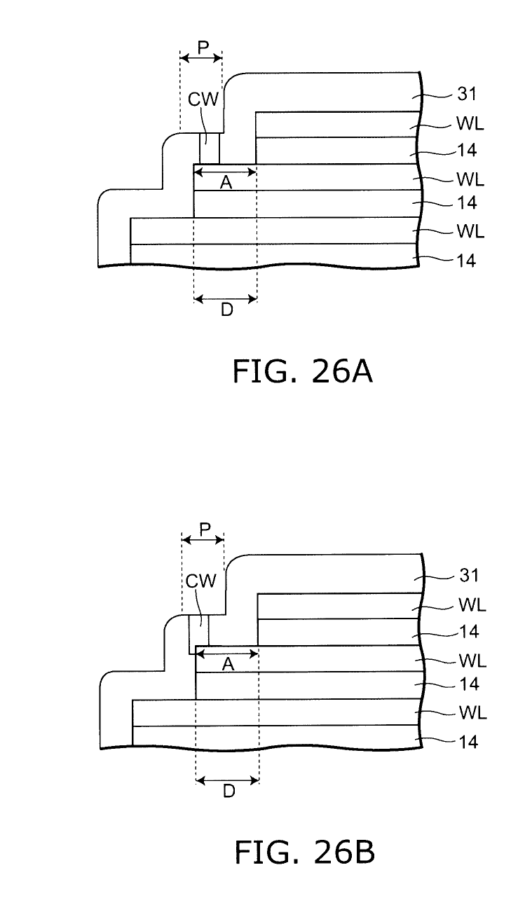

FIGS. 26A and 26B are schematic cross-sectional views illustrating the operation and effect of this embodiment. FIG. 26A shows the case where the contact is in contact with only the upper surface of the electrode film, and FIG. 26B shows the case where the contact is in contact with the edge of the electrode film.

As shown in FIG. 26A, the portion of the etching stopper film 31 covering the end portion of the multilayer body ML21 is shaped like a staircase, reflecting the staircase shape at the end portion of the multilayer body ML21. That is, it includes a generally flat portion and a generally vertical portion for each electrode film WL. When contact holes are formed in the interlayer dielectric film 32 and the etching stopper film 31, in order to accurately control the etching endpoint, it is necessary to cause each contact hole to reach the flat region P on the upper surface of the etching stopper film 31. Conversely, each step of the etching stopper film 31 needs to have a flat region P large enough to receive a contact hole extending thereto.

If the contact CW is brought into contact with only the upper surface of the electrode film WL, the width of the overlapping portion between the flat region P and the end region A of the electrode film WL where no upper electrode film WL is located immediately thereabove needs to be equal to or greater than the diameter of the contact CW. Thus, as viewed from above (Z direction), the distance D between the ends of adjacent electrode films WL needs to be larger than a certain size.

In contrast, in this embodiment, as shown in FIG. 26B, the contact CW is brought into contact with the edge E of the electrode film WL. Hence, the width of the overlapping portion between the end region A and the flat region P does not necessarily need to be equal to or greater than the diameter of the contact CW. Thus, the distance D can be reduced to arrange the contacts CW more densely, and the chip area of the device can be reduced. It is noted that as shown in FIG. 1, the contacts can be displaced in the Y direction, and hence insulation between the contacts is ensured even if the distance D is reduced. The operation and effect of this embodiment other than the foregoing are the same as those of the above first embodiment.

In this embodiment, by way of example, the contacts CW0-CW3 connected to the lower multilayer body ML21 are brought into contact with the edge E of the electrode films WL. However, the invention is not limited thereto. The contacts CW4-CW7 connected to the upper multilayer body ML22 may be brought into contact with the edge E of the electrode films WL. Furthermore, the contacts CW may be brought into contact with the edge E of the electrode films WL for both the multilayer bodies ML21 and ML22. Moreover, this embodiment can also be practiced in combination with the above second embodiment.

The invention has been described with reference to the embodiments. However, the invention is not limited to these embodiments. For example, those skilled in the art can suitably modify the above embodiments by addition, deletion, or design change of components, or by addition, omission, or condition change of processes, and such modifications are also encompassed within the scope of the invention as long as they fall within the spirit of the invention.

1. A semiconductor memory device comprising:
a substrate;
a plurality of multilayer bodies stacked on the substrate, each of multilayer body including a plurality of dielectric films and a plurality of electrode films that are alternately layered, and having an end portion of a staircase shape;
a plurality of interlayer dielectric films provided around the respective multilayer bodies; and
a plurality of contacts buried so as to penetrate through the plurality of interlayer dielectric films and connected to respective end portions of the electrode films,
the contact having a step difference at a position that is located between the interlayer dielectric films.

2. The memory device according to claim 1, further comprising:
a dielectric film located between the contact and the interlayer dielectric films other than the uppermost one of the interlayer dielectric films and formed from a material that is different from the material of the interlayer dielectric films.

3. The memory device according to claim 1, wherein the contact is formed from metal.

4. The memory device according to claim 3, wherein the contact is formed from tungsten.

5. The memory device according to claim 3, further comprising:
a barrier metal layer formed on a surface of the contact.

6. The memory device according to claim 1, wherein the portion of the contact located in each of the interlayer dielectric films has a tapered shape which has a diameter decreasing downward.

7. The memory device according to claim 1, wherein the portion of the contact located in each of the interlayer dielectric films has a barrel shape which has a relatively narrow upper end and lower end and a relatively wide center portion.

8. The memory device according to claim 1, further comprising:
an etching stopper film provided between the interlayer dielectric films and formed from a material that is different from the material of the interlayer dielectric films,
the step being formed at a position in the contact corresponding to the boundary between the etching stopper film and the interlayer dielectric film therebelow.

9. The memory device according to claim 1, wherein as viewed from above, the lower end of the portion of the contact located above the step difference is entirely located inside the upper end of the portion of the contact located below the step difference.

10. The memory device according to claim 1, wherein as viewed from above, the lower end of the portion of the contact located above the step difference is only partly located inside the upper end of the portion of the contact located below the step difference.

11. The memory device according to claim 1, wherein the contact and the electrode film are formed from the same conductive material including a metal, and no barrier metal layer is interposed between the contact and the electrode film.

12. The memory device according to claim 11, wherein the conductive material is silicon-containing aluminum.

13. The memory device according to claim 1, wherein at least one of the contacts is in contact with an edge between the upper surface and the side surface of the electrode film.

14. A method for manufacturing a semiconductor memory device, comprising:
forming a first multilayer body by alternately layering a plurality of dielectric films and a plurality of electrode films on a substrate;
processing an end portion of the first multilayer body into a staircase shape;
forming a first interlayer dielectric film around the first multilayer body;
forming a first contact hole having a diameter decreasing downward in the first interlayer dielectric film so that the first contact hole reaches an end portion of the electrode film;
burying a sacrificial material in the first contact hole;
forming a second multilayer body by alternately layering a plurality of dielectric films and a plurality of electrode films immediately above the first multilayer body;
forming a second interlayer dielectric film around the second multilayer body;
forming a second contact hole having a diameter decreasing downward in the second interlayer dielectric film so that the second contact hole reaches the first contact hole;
removing the sacrificial material; and
burying a contact inside the first contact hole and the second contact hole.

15. The method for manufacturing a memory device according to claim 14, wherein
the forming a first interlayer dielectric film includes:
forming a first etching stopper film on the upper and lateral sides of the first multilayer body;
depositing a first dielectric material entirely on the first etching stopper film, the first dielectric material being different from the dielectric material of the first etching stopper film; and
performing planarization using the first etching stopper film as a stopper, and
the forming a second interlayer dielectric film includes:
forming a second etching stopper film so as to cover the first interlayer dielectric film and the second multilayer body;
depositing a second dielectric material entirely on the second etching stopper film, the second dielectric material being different from the dielectric material of the second etching stopper film; and
performing planarization using the second etching stopper film as a stopper.

16. The method for manufacturing a memory device according to claim 15, wherein
the forming a first contact hole includes:
forming a sub-hole to a depth reaching the first etching stopper film by etching the first dielectric material; and
etching the first etching stopper film exposed to the bottom surface of the sub-hole, and
the forming a second contact hole includes:
forming a sub-hole to a depth reaching the second etching stopper film by etching the second dielectric material; and
etching the second etching stopper film exposed to the bottom surface of the sub-hole.

17. The method for manufacturing a memory device according to claim 14, wherein
the electrode film is formed from silicon doped with acceptor,
the sacrificial material is formed from non-doped silicon, and
the removing the sacrificial material is performed by wet etching using alkaline etchant.

18. The method for manufacturing a memory device according to claim 14, wherein
the burying a contact includes:
depositing a metal film inside the first contact hole and the second contact hole and on the upper surface of the second interlayer dielectric film and the upper surface of the second multilayer body;
replacing at least part of a conductive material contained in the electrode films by a metal contained in the metal film; and
removing the metal film deposited on the upper surface of the second interlayer dielectric film and the upper surface of the second multilayer body.

19. The method for manufacturing a memory device according to claim 18, wherein the metal is aluminum, and the conductive material is silicon.

20. The method for manufacturing a memory device according to claim 14, wherein at least one of the first contact holes reaches an edge between the upper surface and the side surface of the electrode film in the forming a first contact hole.
